(19) United States
(12) Patent Application Publication
(10) Pub. No.: US 2012/0281275 A1
(43) Pub. Date: Nov. 8, 2012

(54) Systems and Methods for Determining One or More Characteristics of a Specimen Using Radiation in the Terahertz Range

(75) Inventors: Ady Levy, Sunnyvale, CA (US); Samuel Ngai, San Francisco, CA (US); Christopher F. Bevis, Los Gatos, CA (US); Stefano Concina, Saratoga, CA (US); John Fielden, Los Altos, CA (US); Walter Mieher, Los Gatos, CA (US); Dieter Mueller, Cupertino, CA (US); Neil Richardson, Palo Alto, CA (US); Dan Wack, Los Altos, CA (US); Larry Wagner, San Jose, CA (US)

(73) Assignee: KLA-TENCOR CORPORATION, San Jose, CA (US)

(21) Appl. No.: 13/552,642

(22) Filed: Jul. 19, 2012

Related U.S. Application Data
(62) Division of application No. 12/401,029, filed on Mar. 10, 2009, now abandoned.

(51) Int. Cl. G06K 7/10; B05C 11/00; B05C 9/00; B05C 11/02; B05C 5/02; C23C 16/44

(52) U.S. Cl. 359/350; 118/300; 118/715; 156/345.11; 118/52; 118/696

(57) ABSTRACT

Systems and methods for determining one or more characteristics of a specimen using radiation in the terahertz range are provided. One system includes an illumination subsystem configured to illuminate the specimen with radiation. The system also includes a detection subsystem configured to detect radiation propagating from the specimen in response to illumination of the specimen and to generate output responsive to the detected radiation. The detected radiation includes radiation in the terahertz range. In addition, the system includes a processor configured to determine the one or more characteristics of the specimen using the output.

### CROSS-REFERENCE TO RELATED APPLICATIONS

This application is a divisional of U.S. patent application Ser. No. 12/401,029 entitled “Systems and Methods for Determining One or More Characteristics of a Specimen Using Radiation in the Terahertz Range,” filed Mar. 10, 2009, now abandoned, which is incorporated by reference as if fully set forth herein.

### BACKGROUND OF THE INVENTION

1. Field of the Invention

This invention generally relates to systems and methods for determining one or more characteristics of a specimen using radiation in the terahertz range. Certain embodiments relate to a system configured to generate output responsive to radiation in the terahertz range propagating from a specimen and to determine one or more characteristics of the specimen using the output.

2. Description of the Related Art

The following description and examples are not admitted to be prior art by virtue of their inclusion in this section.

Fabricating semiconductor devices such as logic and memory devices typically includes processing a specimen such as a semiconductor wafer using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CUP), etch, deposition, and ion implantation. Multiple semiconductor devices may be fabricated in an arrangement on a single semiconductor wafer and then separated into individual semiconductor devices.

Inspection processes are used at various steps during semiconductor manufacturing processes to detect defects on specimens to promote higher yield in the manufacturing processes and thus higher profits. Inspection has always been an important part of fabricating semiconductor devices. However, as the dimensions of semiconductor devices decrease, inspection becomes even more important to the successful manufacture of acceptable semiconductor devices because devices having smaller dimensions are more prone to failure due to defects. Therefore, as the dimensions of semiconductor devices decrease, more accurate detection of defects has become necessary since unwanted aberrations in the semiconductor devices caused by defects can significantly impact yield of the manufacturing process.

Another important part of manufacturing yield control is determining information about defects on the specimens such that the cause of the defects can be determined and corrected to thereby reduce the number of defects on other specimens. Often, determining the cause of defects involves identifying the defect type and other attributes of the defects such as size, shape, composition, etc. Since inspection typically only involves detecting defects on the specimens and providing limited information about the defects such as locations of the defects on the specimens, number of defects on the specimens, and sometimes defect size, metrology is often used to determine more information about individual defects than that which can be determined from inspection results. For instance, a metrology tool may be used to revisit defects detected on a wafer and to examine the defects further in some manner either automatically or manually.

Metrology processes are also used to determine one or more characteristics of the specimens themselves, which may include physical characteristics (e.g., dimensions), chemical characteristics (e.g., concentration of one or more materials on the specimen), electrical characteristics (e.g., resistance), etc. These characteristics are usually measured to monitor the specimens being produced by various manufacturing processes. For example, if the manufacturing processes are not producing specimens with the desired characteristics (e.g., due to variations or drift in the manufacturing processes), the manufacturing processes are preferably altered such that specimens with the desired characteristics will be produced thereby increasing yield of the manufacturing processes.

Metrology and inspection may be performed for semiconductor specimens other than wafers for reasons similar to those described above (e.g., to monitor and control, fabrication or manufacturing and to improve yield of fabrication or manufacturing). Metrology and inspection are performed using a number of different techniques, which may vary depending on the specimen being measured or inspected and the measurements or inspection being performed.

In one such example, strain measurements of silicon wafers may be performed today via indirect methods such as near infrared (NIR) reflectance and measurement of carrier mobility. Strain measurements are particularly important to semiconductor manufacturing since it involves fabricating semiconductor devices with many different materials. When dissimilar materials are formed in contact with one another, the materials may exhibit increased stress. For example, when a dielectric thin film is formed on a monocrystalline silicon substrate, stress may be produced in both the dielectric thin film and the monocrystalline silicon substrate. If the stress in either the thin film or the substrate becomes too high, then the thin film and/or the substrate may be damaged. For instance, the substrate may become so warped that it is no longer viable for use in manufacturing semiconductor devices. For example, wafers that are warped may be unsuitable for lithography processes since the focus of the exposure tool will vary across the wafer due to the differences in the position of the uppermost surface of the wafer caused by the warping.

Process and quality monitoring of the manufacturing of silicon ingots is usually performed off-line with analytical techniques such as Fourier Transform Infrared (FTIR) spectroscopy, which suffers from lack of penetration power, and X-ray techniques, which suffer from laborious experimental preparation. In another example, today, the latent image formed in a resist after ultraviolet (UV) or X-ray exposure is not measured and/or monitored. Instead, measurement is made only after the resist coated wafer has been processed. Some lithography process tools may have internal measurement stations. However, instead of directly measuring chemical changes in the resists, these stations measure factors such as resist thickness and alignment and correlate these measurements to chemical changes. In yet another example, today, testing of liquid crystal displays (LCDs), flat panel displays (FPDs) and other similar products is performed by using electron beams to measure electrical properties. However, 100% interrogation of such products is typically needed. Electron beam testing is disadvantageous for such applications because testing is substantially slow and costly.

Accordingly, it would be advantageous to develop systems and methods for determining one or more characteristics of a specimen that do not have one or more of the disadvantages of the currently used methods and systems described above.

### SUMMARY OF TUE INVENTION

The following description of various embodiments of methods, systems, and optical elements is not to be construed in any way as limiting the subject matter of the appended claims.

One embodiment relates to a system configured to determine one or more characteristics of a specimen. The system includes an illumination subsystem configured to illuminate the specimen with radiation. The system also includes a detection subsystem configured to detect radiation propagating from the specimen in response to illumination of the specimen and to generate output responsive to the detected radiation. The detected radiation includes radiation in the terahertz (THz) range. In one embodiment, the radiation in the THz range includes radiation in a range of about 0.1 THz to about 10 THz. In addition, the system includes a processor configured to determine the one or more characteristics of the specimen using the output.

in one embodiment, the illumination subsystem is configured to illuminate the specimen with radiation in the ultraviolet (UV) range. In another embodiment, the illumination subsystem is configured to illuminate the specimen with radiation in the THz range. In an additional embodiment, the illumination subsystem is configured to illuminate the specimen with radiation in the visible range. In a further embodiment, the illumination subsystem is configured to illuminate the specimen with radiation in the infrared (IR) range. In still another embodiment, the illumination subsystem is configured such that the radiation that illuminates the specimen does not include radiation in the THz range.

In one embodiment, the detected radiation includes radiation reflected by the specimen, radiation transmitted by the specimen, radiation scattered by the specimen, or some combination thereof. In another embodiment, the output is responsive to a wavelength, phase, amplitude, energy, intensity, or some combination thereof of the detected radiation. In one such embodiment, the processor is configured to determine the one or more characteristics of the specimen using the wavelength, phase, amplitude, energy, intensity, or some combination thereof of the detected radiation.

In one embodiment, the one or more characteristics include the one or more characteristics as a function of position on the specimen. In another embodiment, the system is configured to determine the one or more characteristics of the specimen during a process performed on the specimen. In some embodiments, the system is configured as a metrology system. In additional embodiments, the system is configured as an inspection system.

In one embodiment, the illumination subsystem includes an optical element that includes one or more materials configured to have at least some material contrast across the optical element. In one such embodiment, the optical element is configured as a photonic crystal optical element. In another embodiment, the detection subsystem includes an optical element that includes one or more materials configured to have at least some material contrast across the optical element. In one such embodiment, the optical element is configured as a photonic crystal optical element.

In one embodiment, the processor is configured to monitor a process performed on the specimen based on the one or more characteristics of the specimen. In another embodiment, the processor is configured to control a process performed on the specimen based on the one or more characteristics of the specimen.

In one embodiment, the specimen includes a strained silicon wafer. In some embodiments, the one or more characteristics include strain of the specimen. In another embodiment, the one or more characteristics include local strain of the specimen. In one embodiment in which the specimen includes a strained silicon wafer, the illumination subsystem is configured to illuminate a strained area on the wafer and an unstrained area on the wafer. In one such embodiment, the detection subsystem is configured to combine the radiation propagating from the strained area and the radiation propagating from the unstrained area to produce a beating frequency in the THz range and to detect the combined radiation.

In one embodiment, the specimen includes a strained material. In one such embodiment, the processor is configured to determine the one or more characteristics of the strained material using the output and output generated by the detection subsystem for a reference strained material. In another embodiment, the processor is configured to determine the one or more characteristics of the specimen using the output and results of a calibration performed by the system using an additional specimen that includes strained and unstrained areas. In a further embodiment, the illumination subsystem includes a probe having a tapered tip and an aperture at an end of the tapered tip through which the radiation is directed to the specimen.

In one embodiment, the specimen includes a silicon ingot. In one such embodiment, the processor is configured to monitor a process for manufacturing the silicon ingot based on the one or more characteristics of the silicon ingot. In another such embodiment, the processor is configured to monitor a quality of the silicon ingot during manufacturing of the silicon ingot based on the one or more characteristics of the silicon ingot.

In one embodiment, the one or more characteristics include concentration of dopants in the specimen, contaminants and impurities in the specimen, voids, cracks, and other subsurface defects in the specimen, or some combination thereof. In one embodiment in which the specimen includes a silicon ingot, the system is configured to determine the one or more characteristics of the silicon ingot during slicing of the silicon ingot into wafers. In one such embodiment, the processor is configured to determine start and stop points for the slicing during the slicing based on the one or more characteristics of the silicon ingot.

In another embodiment in which the specimen includes a silicon ingot, the illumination subsystem is configured to illuminate the silicon ingot by directing radiation to a surface of the silicon ingot that is substantially perpendicular to an axis of the silicon ingot. In an additional embodiment in which the specimen includes a silicon ingot, the illumination subsystem is configured to illuminate the silicon ingot by directing the radiation to the silicon ingot in a plane of incidence substantially parallel to a radius of the silicon ingot.

As described above, the specimen may include a silicon ingot. In one such embodiment, the one or more characteristics include one or more characteristics of contamination in the silicon ingot, and the contamination includes oxygen contamination, carbon contamination, or some combination thereof in another such embodiment, the one or more characteristics include one or more characteristics of defects in the silicon ingot, and the defects include point defects, line defects, volume defects, or some combination thereof. In one embodiment, the specimen includes a getter layer formed in a silicon wafer, and the one or more characteristics include one or more characteristics of defects in the getter layer.

In one embodiment, the specimen includes a resist formed on a wafer. In one such embodiment, a latent image is formed in the resist. In another such embodiment, the resist has been exposed in an exposure process. In an additional such embodiment, the illumination subsystem is configured to illuminate exposed and unexposed regions of the resist with the radiation.

As described above, the specimen may include a resist formed on a wafer. In one such embodiment, the one or more characteristics include a characteristic of one or more chemical changes in the resist. In another such embodiment, the one or more characteristics include a characteristic of one or more chemical changes in the resist, and the processor is configured to determine one or more variations in exposure of the resist based on the characteristic of the one or more chemical changes in the resist.

In one embodiment, the specimen includes a printed circuit board (PCB) in which vias are formed. In one such embodiment, the one or more characteristics include one or more characteristics of defects in the vias. In another such embodiment, the one or more characteristics include one or more characteristics of subsurface defects in the vias. In a further embodiment, the one or more characteristics include one or more characteristics of defects in the vias as a function of position on the PCB.

In one embodiment, the specimen includes a flat panel display (FPD). In one such embodiment, the one or more characteristics include one or more characteristics of defects in the FPD. In another such embodiment, the system is configured to apply an electric field across a liquid crystal layer of the FPD, and the detection subsystem is configured to detect the radiation before and after the electric field is applied to the liquid crystal layer. In some such embodiments, the processor is configured to determine changes in the detected radiation before and after the electric field is applied to the liquid crystal layer, and the processor is configured to determine the one or more characteristics based on the changes. In one such embodiment, the one or more characteristics include functionality of a FPD cell formed by the liquid crystal layer.

As described above, the specimen may include a FPD. In one such embodiment, the one or more characteristics include functionality of cells in the FPD as a function of position across the FPD. In another such embodiment, the one or more characteristics include voltage build-up behavior of a transparent conductive layer formed within pixels of the FPD. In a further such embodiment, the illumination subsystem is configured to illuminate the FPD using a non-contact technique, and the detection subsystem is configured to detect the radiation propagating from the FPD using anon-contact technique.

In one embodiment, the specimen includes a liquid crystal display (LCD). In one such embodiment, the one or more characteristics include voltage build-up behavior of a transparent conductive layer formed within pixels of the LCD. In another such embodiment, the illumination subsystem is configured to illuminate the LCD using a non-contact technique, and the detection subsystem is configured to detect the radiation propagating from the LCD using a non-contact technique.

In one embodiment, the specimen includes a solar cell panel. In one such embodiment, the one or more characteristics include carrier concentration in the solar cell panel. In another such embodiment, the one or more characteristics include carrier lifetime in the solar cell panel. In an additional such embodiment, the one or more characteristics include the one or more characteristics as a function of position across the solar cell panel.

In one embodiment, the specimen includes a low k dielectric material formed on a substrate. In one such embodiment, the one or more characteristics include one or more characteristics of porosity, delamination, composition of one or more elements in the dielectric material, or some combination thereof. In another such embodiment, the one or more characteristics include the one or more characteristics as a function of position on the low k dielectric material.

in one embodiment, the specimen includes a layer of borophosphosilicate glass (BPSG) formed on a substrate. In one such embodiment, the one or more characteristics include concentration of boron in the layer, concentration of phosphorus in the layer, or some combination thereof. In another such embodiment, the one or more characteristics include the one or more characteristics as a function of position on the layer.

In one embodiment, the specimen includes gallium nitride (GaN). In one such embodiment, the one or more characteristics include concentration of the GaN, content distribution of the GaN, or some combination thereof. In another embodiment, the system is configured to determine the one or more characteristics of the GaN during a process performed for the GaN. In a further such embodiment, the one or more characteristics include the one or more characteristics as a function of position on the GaN. In yet another such embodiment, the one or more characteristics include the one or more characteristics as a function of position on the GaN, and the processor is configured to monitor or control a GaN manufacturing process based on the one or more characteristics as the function of the position on the GaN.

In one embodiment, the specimen includes a material grown in a substrate during a metal organic chemical vapor deposition (MOCVD) process. In one such embodiment, the one or more characteristics include concentration of the material in the substrate. In another such embodiment, the one or more characteristics include the one or more characteristics as a function of position across the substrate. In one such embodiment, the processor is configured to monitor or control the MOCVD process based on the one or more characteristics as the function of the position across the substrate.

Each of the embodiments of the system described above may be further configured as described herein (e.g., according to any other system embodiment(s) described herein).

Another embodiment relates to a system configured to determine one or more characteristics of one or more chemical vapors, one or more deposited materials, or some combination thereof in a chamber of a MOCVD reactor. This system includes an illumination subsystem configured to illuminate an interior of the chamber of the MOCVD reactor with radiation in the THz range. The system also includes a detection subsystem configured to detect radiation propagating from the interior of the chamber in response to illumination of the interior of the chamber and to generate output responsive to the detected radiation. The detected radiation includes radiation in the THz range. In addition, the system includes a processor configured to determine one or more characteristics of the one or more chemical vapors, the one or more deposited materials, or some combination thereof using the output.

In one embodiment, the one or more characteristics include vapor content of the one or more chemical vapors, the one or more deposited materials, or some combination thereof. In another embodiment, the detected radiation includes reflected radiation, transmitted radiation, scattered radiation, or some combination thereof. In an additional embodiment, the output is responsive to a wavelength, phase, amplitude, energy, intensity, or some combination thereof of the detected radiation, and the processor is configured to determine the one or more characteristics of the one or more chemical vapors, the one or more deposited materials, or some combination thereof using the wavelength, phase, amplitude, energy, intensity, or some combination thereof of the detected radiation. In a further embodiment, the one or more characteristics include vapor content of the one or more chemical vapors, the one or more deposited materials, or some combination thereof and the processor is configured to monitor or control the MOCVD process based on the vapor content.

Each of the embodiments of the system described above may be further configured as described herein (e.g., according to any other system embodiment(s) described herein).

An additional embodiment relates to a method for determining one or more characteristics of a specimen. The method includes illuminating the specimen with radiation. The method also includes detecting radiation propagating from the specimen in response to the illuminating step to generate output responsive to the detected radiation. The detected radiation includes radiation in the THz range. In addition, the method includes determining the one or more characteristics of the specimen using the output.

Each of the steps of the method described above may be performed as described further herein. In addition, the embodiment of the method described above may include any other step(s) of any other method(s) described herein. Furthermore, the embodiment of the method described above may be performed by any of the systems described herein.

A further embodiment relates to an optical element configured for use in a system configured to determine one or more characteristics of a specimen. The optical element includes one or more materials configured to have at least some material contrast across the optical element. The one or more materials are further configured such that the optical element can be used for radiation in the THz range.

In one embodiment, the optical element is configured as a waveguide. In another embodiment, the optical element is configured as a filter. In an additional embodiment, the optical element is configured as a beam splitter. In yet another embodiment, the optical element is configured as a photonic crystal optical element.

In some embodiments, the one or more materials include ink printed on a substrate. In another embodiment, the one or more materials include a dielectric material. In an additional embodiment, the one or more materials include a semiconductive material. In a further embodiment, the one or more materials include a metal material. In yet another embodiment, the one or more materials include a plastic material.

In some embodiments, the one or more materials include a material having openings formed therein. In one such embodiment, the openings are filled with air. In another such embodiment, the openings are filled with a vacuum. In an additional embodiment, the one or more materials include a single material having openings formed therein, and the openings create the material contrast.

In another embodiment, the one or more materials form patterned features of the optical element. In one such embodiment, the one or more materials include ink printed on a substrate, and each of the pattered features is formed of multiple spots of the ink. In another such embodiment, each of the patterned features has a size of about 10 microns to about 100 microns. In some embodiments, the one or more materials include a substrate formed of a plastic material.

Each of the embodiments of the optical element described above may be further configured as described herein (e.g., according to any other embodiment(s) described herein). In addition, each of the embodiments of the optical element described above may be included in any of the system embodiments described herein.

Still another embodiment relates to a system configured to fabricate an optical element. The system includes a fabrication subsystem configured to create at least some material contrast across the optical element in one or more materials of the optical element to thereby fabricate the optical element. The one or more materials are configured such that the optical element can be used for radiation in the THz range.

In one embodiment, the fabrication subsystem includes a print head configured to form the one or more materials on a substrate, and the one or more materials include ink. In another embodiment, the fabrication subsystem includes a lithography system. In an additional embodiment, the fabrication subsystem includes a deposition system. In a further embodiment, the fabrication subsystem includes an etch system. In some embodiments, the fabrication subsystem includes a spin processing system.

In one embodiment, the system includes a computer aided design (CAD) system configured to generate a design for patterned features of the optical element formed by the one or more materials. In one such embodiment, the system also includes a processor configured to perform one or more electromagnetic calculations to verify the design.

In one embodiment, the optical element is configured as a waveguide. In another embodiment, the optical element is configured as a filter. In an additional embodiment, the optical element is configured as a beam splitter. In yet another embodiment, the optical element is configured as a photonic crystal optical element.

In one embodiment, the one or more materials include ink printed on a substrate. In another embodiment, the one or more materials include a dielectric material. In an additional embodiment, the one or more materials include a semiconductive material. In a further embodiment, the one or more materials include a metal material. In some embodiments, the one or more materials include a plastic material.

In one embodiment, the one or more materials include a material having openings formed therein. In one such embodiment, the openings are filled with air. In another such embodiment, the openings are filled with a vacuum. In some embodiments, the one or more materials include a single material having openings formed therein, and the openings create the material contrast.

In another embodiment, the one or more materials form patterned features of the optical element. In one such embodiment, the one or more materials include ink printed on a substrate, and each of the patterned features is formed of multiple spots of the ink. In another such embodiment, each of the patterned features has a size of about 10 microns to about 100 microns. In some embodiments, the one or more materials include a substrate formed of a plastic material.

Each of the embodiments of the system described above may be further configured as described herein (e.g., according to any other system embodiment(s) described herein).

### BRIEF DESCRIPTION OF THE DRAWINGS

Other objects and advantages of the invention will become apparent upon reading the following detailed description and upon reference to the accompanying drawings in which:

FIGS. 1-2 are schematic diagrams illustrating a side view of various embodiments of a system configured to determine one or more characteristics of a specimen;

FIG. 2a is a schematic diagram illustrating a cross-sectional view of one embodiment of a probe that may be included in the illumination subsystem of the system shown in FIG. 2;

FIG. 3 includes plots showing different examples of results that may be generated by the embodiments described herein;

FIGS. 4-5 are schematic diagrams illustrating a perspective view of various embodiments of a system configured to determine one or more characteristics of a specimen;

FIGS. 6-7 are schematic diagrams illustrating a perspective view of examples of a specimen for which one or more characteristics may be determined by the embodiments described herein;

FIG. 8 is a schematic diagram illustrating a side view of another embodiment of a system configured to determine one or more characteristics of a specimen;

FIG. 9 is a schematic diagram illustrating a top view of one example of a specimen for which one or more characteristics may be determined by the embodiments described herein, one example of a path in which the specimen may be exposed in an exposure process, and one embodiment of a path in which characteristic(s) of the specimen may be determined by embodiments described herein;

FIGS. 10-11 are schematic diagrams illustrating a side view of various embodiments of a system configured to determine one or more characteristics of a specimen;

FIG. 12 is a schematic diagram illustrating a perspective view of one example of a specimen for which one or more characteristics may be determined by the embodiments described herein;

FIG. 13 is a schematic diagram illustrating one pixel of the specimen shown in FIG. 12;

FIGS. 14-15 are plots illustrating examples of results that may be generated by the embodiments described herein;

FIGS. 16-17 are schematic diagrams illustrating a side view of various embodiments of a system configured to determine one or more characteristics of a specimen;

FIG. 18 is a schematic diagram illustrating a side view of one embodiment of a system configured to determine one or more characteristics of one or more chemical vapors, one or more deposited materials, or some combination thereof in a chamber of a metal organic chemical vapor deposition (MOCVD) reactor;

FIG. 19 is a schematic diagram illustrating a top view of various embodiments of a two-dimensional photonic crystal structure;

FIG. 20 is a schematic diagram illustrating a cross-sectional view of one embodiment of an optical element configured for use in a system configured to determine one or more characteristics of a specimen; and

FIG. 21 is a schematic diagram illustrating a side view of one embodiment of a system configured to fabricate an optical element.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals.

In general, the embodiments described herein are configured for using electromagnetic radiation in the terahertz (THz) range (e.g., radiation in a range of about 0.1 THz to about 10 THz) for metrology and inspection applications in the manufacturing of semiconductor or related devices.

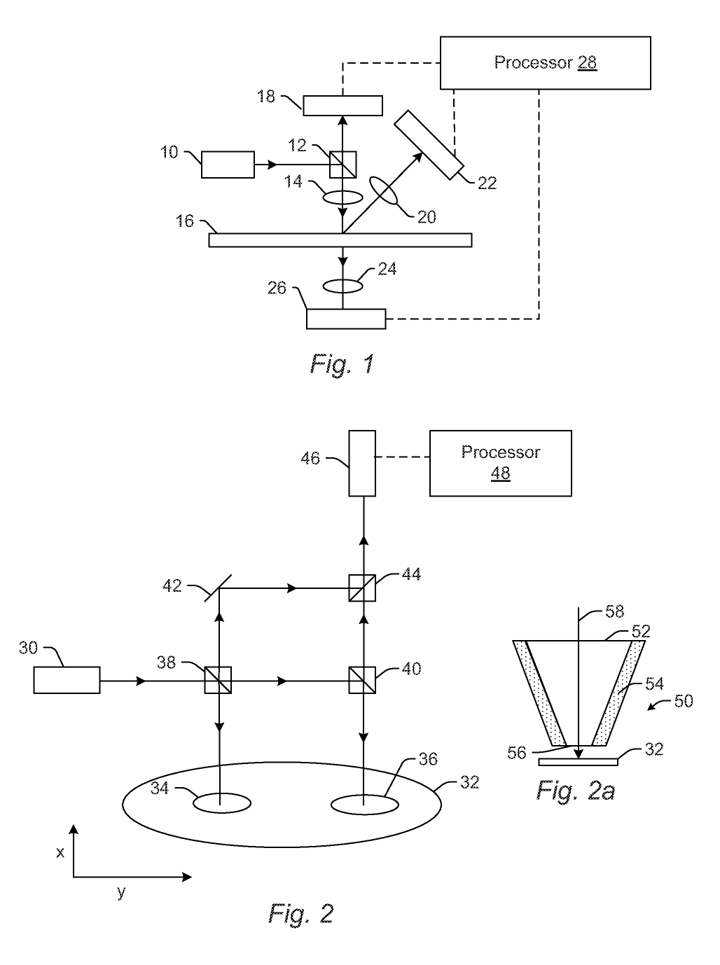

One embodiment relates to a system configured to determine one or more characteristics of a specimen. One embodiment of such a system is shown in FIG. 1. The system shown in FIG. 1 includes an illumination subsystem configured to illuminate the specimen with radiation. For example, the illumination subsystem includes radiation source 10, which may vary depending on the radiation with which the illumination subsystem is configured to illuminate the specimen. In a preferred embodiment, the illumination subsystem is configured to illuminate the specimen with radiation that causes radiation in the THz range to propagate (e.g., by reflection, scattering, diffraction, transmission, etc.) from the specimen. For example, in one embodiment, the illumination subsystem is configured to illuminate the specimen with radiation in the ultraviolet (UV) range. In one such embodiment, radiation source 10 may include a laser configured to generate UV light. In another embodiment, the illumination subsystem is configured to illuminate the specimen with radiation in the THz range. In such embodiments, radiation source 10 may include any source that can generate radiation in the THz range. In another embodiment, the illumination subsystem is configured to illuminate the specimen with radiation in the visible range. In one such embodiment, radiation source 10 may include any source that can generate radiation in the visible range. In an additional embodiment, the illumination subsystem is configured to illuminate the specimen with radiation in the infrared (IR) range. In such an embodiment, radiation source 10 may include any source that can generate radiation in the IR range. In addition, the illumination subsystem may be configured to illuminate the specimen with some combination of radiation in the UV range, radiation in the THz range, radiation in the visible range, and radiation in the IR range. Alternatively, the illumination subsystem may be configured to illuminate the specimen with only radiation in the UV range, only radiation in the THz range, only radiation in the visible range, or only radiation in the IR range.

In still another embodiment, the illumination subsystem is configured such that the radiation that illuminates the specimen does not include radiation in the THz range. In this manner, the specimen may be illuminated with non-THz radiation (e.g., only non-THz radiation). For example, the illumination subsystem may be configured to illuminate the specimen with radiation in the UV range, radiation in the visible range, radiation in the IR range, or some combination thereof; but not radiation in the THz range.

In another embodiment, the illumination subsystem includes two or more radiation sources (not shown), and the illumination subsystem may be configured to illuminate the specimen with radiation generated by one or more of the radiation sources. The two or more radiation sources may include, for example, one or more radiation sources configured to generate UV light, one or more radiation sources configured to generate radiation in at least the THz range, one or more radiation sources configured to generate radiation in at least the visible range, one or more radiation sources configured to generate radiation in at least the IR range, or some combination thereof. In this manner, the illumination subsystem may include different radiation sources, which are used for sequential and/or simultaneous illumination of the specimen in only some or all of the different ranges. However, the illumination subsystem may include a radiation source that is used for illumination in multiple, different ranges. For example, the illumination subsystem may include a radiation source that is used for illumination of the specimen in some combination of the UV range, the visible range, and the IR range. Such an illumination subsystem may also include any additional radiation source(s) that can be used for illumination in any of the range(s) described herein.

The illumination subsystem may also include beam splitter 12 that is configured to direct radiation from radiation source 10 to lens 14. Beam splitter 12 may include any suitable optical element known in the art and may be selected based on the radiation with which the specimen will be illuminated and the radiation propagating from the specimen that will be detected. Lens 14 may include any suitable optical element known in the art and may also be selected based on the radiation with which the specimen will be illuminated and the radiation propagating from the specimen that will be detected. Lens 14 may be configured to focus the radiation to specimen 16. Specimen 16 may include any of the specimens described herein or any other suitable specimens known in the art.

As shown in FIG. 1, the illumination subsystem may be configured such that the radiation is directed to the specimen at a substantially normal angle of incidence (e.g., a normal angle of incidence or a near normal angle of incidence). However, in other embodiments, the illumination subsystem may be configured to illuminate the specimen by directing the radiation to the specimen at an oblique angle of incidence. The oblique angle of incidence may be any suitable oblique angle of incidence.

The illumination subsystem may also include any other optical elements described herein (not shown in FIG. 1). For example, in one embodiment, the illumination subsystem includes an optical element that includes one or more materials configured to have at least some material contrast across the optical element. Such art optical element may be configured as described herein. In one such embodiment, the optical element is configured as a photonic crystal optical element. The photonic crystal optical element may be configured as described herein. The illumination subsystem may also include one or more such optical elements, which may be positioned at any suitable location(s) within the illumination subsystem. For example, the illumination subsystem may include such an optical element positioned between radiation source 10 and beam splitter 12 or between beam splitter 12 and lens 14. The illumination subsystem may include any other suitable optical elements (not shown) such as waveguides, filters, etc., which may be configured as described further herein.

The system shown in FIG. 1 also includes a detection subsystem configured to detect radiation propagating from the specimen in response to illumination of the specimen and to generate output responsive to the detected radiation. The detected radiation includes radiation in the THz range. The detected radiation may also include radiation in the THz range in combination with radiation in one or more other ranges such as those described above (e.g., the UV range, the visible range, the IR range, or some combination thereof). In one embodiment, the detected radiation includes radiation reflected by the specimen, radiation transmitted by the specimen, radiation scattered by the specimen, or some combination thereof. For example, the detection subsystem shown in FIG. 1 includes detector 18 configured to detect radiation reflected by the specimen. In particular, radiation reflected (specularly reflected) by the specimen may pass through lens 14 and beam splitter 12 to detector 18. Therefore, lens 14, beam splitter 12, and detector 18 may form one channel of the detection subsystem. Detector 18 may include any detector that can be used to detect radiation in the THz range. In addition, the detection subsystem may include more than one channel (not shown) configured to detect radiation reflected by the specimen, each of which may be configured to detect radiation having one or more different characteristics such as wavelength and polarization.

The detection subsystem shown in FIG. 1 also includes lens 20 that is configured to collect radiation scattered from the specimen. Lens 20 may include any suitable optical element or elements known in the art. Lens 20 may be configured to collect radiation scattered from the specimen across any range of azimuthal and polar angles. Scattered radiation collected by lens 20 is directed to detector 22, which may include any detector that can be used to detect radiation in the THz range. Therefore, lens 20 and detector 22 form another channel of the detection subsystem. In addition, although the detection subsystem shown in FIG. 1 includes one channel configured to detect radiation scattered from the specimen, it is to be understood that the detection subsystem may include any suitable number of channels configured to detect scattered radiation. Each of the channels may be configured to detect radiation scattered across a unique range of azimuthal and polar angles or the same range of angles. In addition, each of the channels may be configured to detect scattered radiation having the same characteristics such as wavelength and polarization or one or more different characteristics.

The detection subsystem shown in FIG. 1 also includes lens 24 that is configured to collect radiation transmitted by the specimen. Lens 24 may include any suitable optical element or elements known in the art. Lens 24 may be configured to collect radiation transmitted by the specimen across any range of azimuthal and polar angles. Transmitted radiation collected by lens 24 is directed to detector 26, which may include any detector that can be used to detect radiation in the THz range. Therefore, lens 24 and detector 26 form another channel of the detection subsystem. In addition, although the detection subsystem shown in FIG. 1 includes one channel configured to detect radiation transmitted by the specimen, it is to be understood that the detection subsystem may include any suitable number of channels configured to detect transmitted radiation. Each of the channels may be configured to detect radiation transmitted across a unique range of azimuthal and polar angles or the same range of angles. In addition, each of the channels may be configured to detect transmitted radiation having the same characteristics such as wavelength and polarization or one or more different characteristics.

The detection subsystem may also include any other optical elements described herein (not shown in FIG. 1). For example, in one embodiment, the detection subsystem includes an optical element that includes one or more materials configured to have at least some material contrast across the optical element. Such an optical element may be configured as described herein. In one such embodiment, the optical element is configured as a photonic crystal optical element. The photonic crystal optical element may be configured as described herein. The detection subsystem may also include one or more such optical elements, which may be positioned at any suitable location(s) within the detection subsystem. For example, the detection subsystem may include such an optical element positioned between lens 20 and detector 22. In addition, one or more channels of the detection subsystem may include one or more such optical elements. The detection subsystem may include any other suitable optical elements (not shown) such as waveguides, filters, etc., which may be configured as described further herein.

The system shown in FIG. 1 also includes processor 28. Output generated by each of the detectors included in the detection subsystem may be provided to processor 28. For example, the processor may be coupled to each of the detectors (e.g., by one or more transmission media shown by the dashed lines in FIG. 1, which may include any suitable transmission media known in the art) such that the processor can receive the output generated by the detectors. The processor may be coupled to each of the detectors in any other suitable manner.

The processor is configured to determine the one or more characteristics of the specimen using the output generated by the detection subsystem. The output used to determine the one or more characteristics of the specimen may include output generated by any one or more channels (or detectors) of the system. The processor may be configured to determine the one or more characteristics of the specimen as described farther herein. For example, in one embodiment, the output generated by the detection subsystem is responsive to a wavelength, phase, amplitude, energy, intensity, or some combination thereof of the detected radiation. In one such embodiment, the processor is configured to determine the one or more characteristics of the specimen using the wavelength, phase, amplitude, energy, intensity, or some combination thereof. However, the processor may be configured to determine the one or more characteristics of the specimen using any other suitable method and/or algorithm. The one or more characteristics may include any of the characteristic(s) described further herein.

For example, in one embodiment, the one or more characteristics include the one or more characteristics as a function of position on the specimen. In one such embodiment, the system may be configured to move the specimen with respect to the illumination and detection subsystems such that output can be generated at different positions on the specimen. For example, the system may include a stage (not shown) on which the specimen is disposed during illumination and detection of the radiation propagating from the specimen. The stage may include any suitable mechanical and/or robotic assembly that can be controlled to alter a position of the specimen with respect to the illumination and detection subsystems. In another such embodiment, the system may be configured to move the illumination and detection subsystems with respect to the specimen such that output can be generated at different positions on the specimen. The system may be configured to move the illumination and detection subsystems in any suitable manner using any suitable device and/or method.

In some embodiments, the system may be configured to maintain a position of the specimen with respect to the illumination and detection subsystems during illumination and detection of the radiation. In another embodiment, the system may be configured to move the specimen and/or the illumination and detection subsystems such that the illumination can be scanned over the specimen while the radiation is being detected. In this manner, the system may be configured as a scanning type system. The system may also be configured such that the specimen can be scanned by the illumination and detection subsystems along any suitable direction or directions known in the art. For example, the system may be configured to scan the specimen in the x and y directions in a serpentine fashion. Alternatively, the system may be configured to scan the specimen by rotating and translating the specimen such that a spiral type path is scanned on the specimen.

In some embodiments, the system is configured to determine the one or more characteristics of the specimen during a process performed on the specimen. For example, the system shown in FIG. 1 may be coupled to a process tool (not shown in FIG. 1), which may include any process tool that can be used to perform a process on the specimen. The system shown in FIG. 1 may be coupled to a process tool as described further herein. Therefore, the system shown in FIG. 1 may be configured to determine the one or more characteristics of the specimen during a process performed on the specimen.

In one embodiment, the processor is configured to monitor a process performed on the specimen based on the one or more characteristics of the specimen. In another embodiment, the processor is configured to control a process performed on the specimen based on the one or more characteristics of the specimen. The processor may be configured to monitor and/or control the process based on any of the characteristics of any of the specimens described herein. The process that is monitored and/or controlled by the processor may include any process described herein or any other process known in the art that can be performed on the specimens described herein. The process may be performed on the specimen prior to determining the characteristic(s), during determining the characteristic(s), or after determining the characteristic(s).

The processor may be configured to monitor the process using any method and/or algorithm known in the art such as a statistical process control (SPC) method. In addition, the processor may be configured to control the process using any method, algorithm, and/or technique known in the art such as a feedback control technique, a feedforward control technique, an in situ control technique, or some combination thereof. The processor may be configured to control the process by altering one or more parameters of the process (e.g., by altering one or more parameters of a process tool used to perform the process on the specimen, by altering one or more parameters of a recipe used to perform the process on the specimen, etc.).

In one embodiment, the system is configured as a metrology system. For example, the one or more characteristics of the specimen that are determined by the system shown in FIG. 1 may include metrology type characteristics of the specimen. The metrology type characteristics may include any measurable characteristics of the specimen. For example, the metrology type characteristics may include one or more measurable characteristics of defects in or on the specimen, concentration of an element in the specimen, one or more chemical characteristics of the specimen, one or more physical characteristics of the specimen, one or more electrical characteristics of the specimen, one or more functional characteristics of the specimen, one or more optical characteristics of the specimen, etc.

In another embodiment, the system is configured as an inspection system. For example, the one or more characteristics of the specimen that are determined by the system shown in FIG. 1 may include inspection type characteristics of the specimen. The inspection type characteristics may include any one or more characteristics of defects on or in the specimen. As used herein, the term “one or more characteristics of defects” may include any characteristic(s) of the defects such as whether or not the defects are present in the specimen, number of defects present in the specimen, locations of defects present in the specimen, spatial distribution of defects present in the specimen, characteristics of individual defects such as size, shape, etc., and the like.

The processor may be included in any suitable computer system. The computer system may take various forms, including a personal computer system, image computer, mainframe computer system, workstation, network appliance. Internet appliance, or other device. In general, the term “computer system” may be broadly defined to encompass any device having one or more processors, which executes instructions from a memory medium. The computer system may also include any suitable processor known in the art such as a parallel processor. In addition, the computer system may include a computer platform with high speed processing and software, either as a standalone or a networked tool.

The processor may be configured to perform any other step(s) of any method embodiment(s) described herein. The system shown in FIG. 1 may also be further configured as described herein.

It is noted that FIG. 1 is provided herein to generally illustrate one embodiment of a configuration for a system configured to determine one or more characteristics of a specimen. Obviously, the system configuration described herein may be altered to optimize the performance of the system as is normally performed when designing a commercial system. In addition, the systems described herein may be implemented by modifying an existing system such as a metrology or inspection system that is commercially available from KLA-Tencor, San Jose, Calif. Alternatively, the systems described herein may be designed “from scratch” to provide a completely new system.

In one embodiment, the specimen includes a strained silicon wafer. In another embodiment, the one or more characteristics include strain of the specimen. In this manner, the embodiments described herein may be configured for strain measurements of strained silicon wafers using radiation in the THz range. One embodiment of such a system is shown in FIG. 2. This embodiment of the system includes an illumination subsystem configured to illuminate the specimen with radiation. In addition, the illumination subsystem may be configured to illuminate the specimen with radiation in the UV range. For example, as shown in FIG. 2, the illumination subsystem includes radiation source 30. Radiation source 30 may be configured to generate radiation in the UV range. For example, radiation source 30 may be a UV laser, which may include any suitable U laser known in the art. In this manner, the wafer sample may be illuminated with a UV laser. In addition, although a UV laser may be used for its relatively narrow bandwidth, the radiation source may include any other suitable UV radiation source known in the art.

The system shown in FIG. 2 may be configured to determine the one or more characteristics of the specimen using a heterodyne approach with a beat frequency in the THz range. The heterodyne approach may advantageously increase the sensitivity of the detected radiation to the one or more characteristics of the specimen. For a better and more usable beat frequency, two different areas of the same wafer, one strained and one unstrained, may be illuminated. For example, in one embodiment in which the specimen includes a strained silicon wafer, the illumination subsystem is configured to illuminate a strained area on the wafer and an unstrained area on the wafer. In one such example, specimen 32 may include a strained silicon wafer having strained area 34 and unstrained area 36. Although one strained area and one unstrained area are shown in FIG. 2 in a particular arrangement, it is to be understood that the strained and unstrained areas on the specimen will vary depending on the specimen itself. The strained and unstrained areas may be identified in any suitable manner.

In one such example, a single radiation source may be used to illuminate both the strained area and the unstrained area. For example, the illumination subsystem may include beam splitters 38 and 40, which may include any suitable beam splitters. Radiation source 30 may be configured to direct radiation to beam splitter 38. Beam splitter 38 may be configured to reflect a portion of the radiation to strained area 34 on the specimen and to allow another portion of the radiation to pass through the beam splitter. Beam splitter 40 may be configured to direct the radiation that passed through beam splitter 38 to unstrained area 36 on the specimen. Although the illumination subsystem is shown in FIG. 2 to illuminate the strained and unstrained areas by directing the radiation to the specimen at substantially normal angles of incidence, it is to be understood that the illumination subsystem may be configured to illuminate the specimen by directing the radiation to the specimen at any suitable angle of incidence (e.g., an oblique angle of incidence). In other embodiments, the system may include two radiation sources (not shown), one of which is used to illuminate a strained area of the specimen and the other of which is used to illuminate an unstrained area of the specimen.

In one embodiment, the illumination subsystem includes a probe having a tapered tip and an aperture at an end of the tapered tip through which the radiation is directed to the specimen. One embodiment of such a probe is illustrated in FIG. 2a. As shown in FIG. 2a, the probe includes tapered tip 50 formed of optical fiber 52 that is coated with metallic material 54 such as aluminum. The optical fiber may be formed of any suitable material. The metallic material is not formed on end 56 of the optical fiber such that the end of the optical fiber forms an aperture at the end of the tapered tip through which radiation 58 is directed to specimen 32. The probe may be positioned in the illumination subsystem such that the probe is positioned relatively close to the specimen. If the illumination subsystem is configured to direct two or more beams of radiation to the specimen, the illumination subsystem may include two or more probes described above, each positioned in the path of one of the beams and relatively close to the specimen. In this manner, the system shown in FIG. 2 may also be configured for tip enhancement. For example, the quality of the reflected or transmitted or scattered and the combined THz signals can be enhanced by using a relatively sharp metallic tip to alter the local field (e.g., to enhance the resolution of the system). The probe may include any other suitable probe known in the art.

Light beams are reflected or transmitted or scattered from the two illuminated areas. The system shown in FIG. 2 also includes a detection subsystem configured to detect radiation propagating from the specimen in response to illumination of the specimen and to generate output responsive to the detected radiation. The detected radiation includes radiation in the THz range. In one embodiment in which the illumination subsystem is configured to illuminate a strained area and an unstrained area on a strained silicon wafer, the detection subsystem is configured to combine the radiation propagating from the strained area and the radiation propagating from the unstrained area to produce a beating frequency in the THz range and to detect the combined radiation. For example, the detection subsystem may include beam splitters 38 and 40, reflective optical element 42, beam combiner 44, and detector 46. In one such example, radiation reflected from strained area 34 may pass through beam splitter 38 and may be reflected by reflective optical element 42 to beam combiner 44. Reflective optical element 42 may include any suitable reflective optical element such as a flat mirror. Beam combiner 44 may include any suitable beam combiner known in the art. Radiation reflected from unstrained area 36 may pass through beam splitter 40 to beam combiner 44.

Beam combiner 44 may be configured to combine the radiation reflected by reflective optical element 42 and the radiation transmitted by beam splitter 40. The resulting combined radiation may be directed from beam combiner 44 to detector 46. Detector 46 may be configured as described above. Although the detection subsystem shown in FIG. 2 is configured to detect radiation reflected from a strained area combined with radiation reflected from an unstrained area on the specimen, the detection subsystem may also or alternatively be configured to detect radiation scattered from a strained area combined with radiation scattered from an unstrained area on the specimen. In additional embodiments, the detection subsystem may also or alternatively be configured to detect radiation transmitted by a strained area on the specimen combined with radiation transmitted by an unstrained area on the specimen. In this manner, two reflected or transmitted or scattered beams may be combined to produce a beating frequency in the THz range. Therefore, the combined THz signal is detected by the detection subsystem.

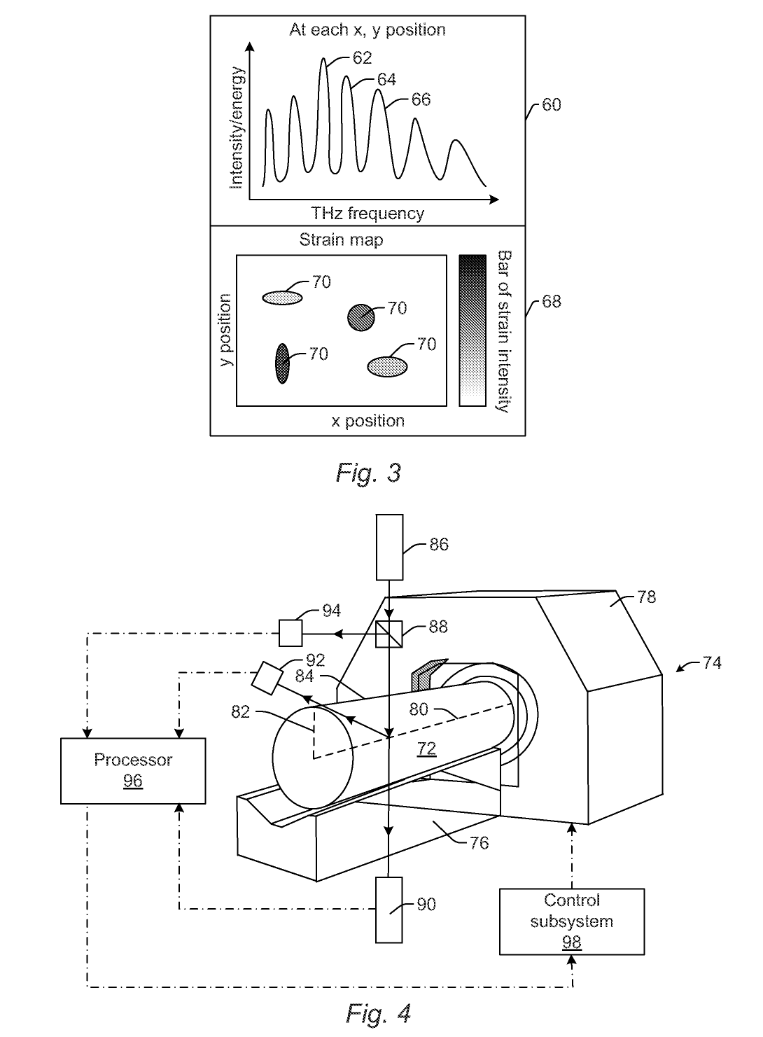

The system shown in FIG. 2 also includes processor 48 configured to determine the one or more characteristics of the specimen using the output generated by the detection subsystem. For example, in one embodiment, the one or more characteristics include local strain of the specimen. In particular, the phase, amplitude, energy, intensity, or some combination thereof of the combined THz signal detected as described above is characteristic of the local strain of the wafer sample. For example, as shown in plot 60 of FIG. 3, at each x and y position on the specimen, the intensity or energy of the output of the detection subsystem shown in FIG. 2 may be plotted as a function of THz frequencies. The intensity or energy of the output may include peaks 62, 64, and 66 at different THz frequencies that are characteristic of local strain in the specimen. Therefore, the peaks in the intensity or energy may be used by the processor to determine local strain in the specimen. In this manner, the combined THz signal detected by the detection subsystem may be used by the processor to determine the local strain of the specimen. Processor 48 shown in FIG. 2 may be further configured as described herein.

In one embodiment, the specimen includes a strained material, and the processor is configured to determine the one or more characteristics of the strained material using the output described above and output generated by the detection subsystem for a reference strained material. For example, although the reflected or transmitted or scattered beams that are combined as described above may be beams propagating from the same sample, in some embodiments, a reference strained material (not shown) and a test strained material (e.g., specimen 32) are illuminated. Beams reflected or transmitted or scattered from the reference strained material and the test strained material may be combined as described above.

The system may be configured to repeat the operation of the system described above over substantially the entire wafer surface (e.g., in a raster fashion) to allow mapping of the combined reflected or transmitted or scattered THz signal (indicative of local strain) as a function of x and y position on the wafer. For example, the processor may be configured to generate plot 68 shown in FIG. 3, which is a strain map indicating the strain intensity as a function of x and y position on the specimen. In particular, areas 70 of local strain on the specimen may be indicated in gray scale according to the bar of strain intensity to indicate areas that have different intensities of strain.

In one embodiment, processor 48 shown in FIG. 2 is configured to determine the one or more characteristics of the specimen using the output and results of a calibration performed by the system using an additional specimen that includes strained and unstrained areas. For example, the processor described above may be configured to calibrate the system. The calibration may be performed such that strain characteristics can be correlated to the detected radiation or the output responsive to the detected radiation. In one such example, to resolve the frequencies in the beat signal, a relatively large area with relatively small islands or a repetitive array of strain is illuminated. Compressive, tensile, and unstrained areas may be assigned according to the phase, amplitude, energy, intensity, or some combination thereof of the THz signal. This approach may be particularly useful for determining one or more characteristics of memory devices or memory areas within a device. Examples of memory include, but are not limited to, flash, DRAM, and SRAM. For example, the approaches described above may be used to determine one or more characteristics of repetitive arrays included in all types of memory. In addition, the memory array for which one or more characteristics are determined may form one section of a device such as a logic device. The system shown in FIG. 2 may be further configured as described herein.

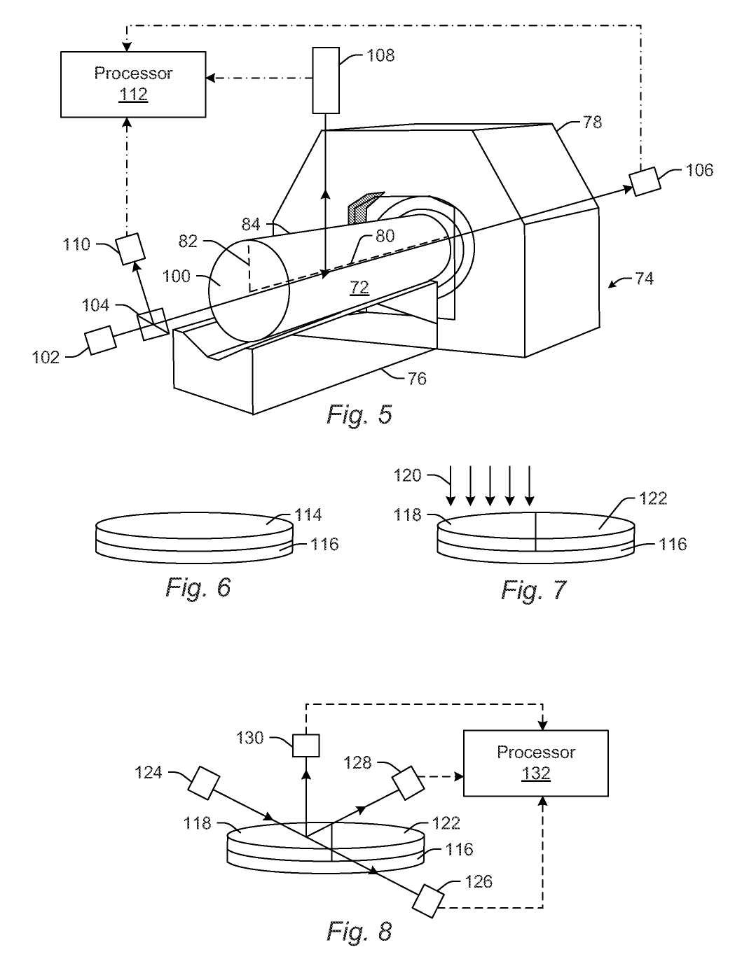

In one embodiment, the specimen includes a silicon ingot. FIGS. 4 and 5 illustrate embodiments of a system configured to determine one or more characteristics of a silicon ingot. In one embodiment, the system is configured for radial monitoring of the silicon ingot. FIG. 4 illustrates one such embodiment of such a system. As shown in FIG. 4, specimen 72 includes a silicon ingot. The silicon ingot may include any silicon ingot known in the art. In some embodiments, the system is configured to determine one or more characteristics of the silicon ingot while the silicon ingot is disposed within and/or being processed by process tool 74. Process tool 74 may be configured as a wafer slicing tool that is configured to slice the silicon ingot into wafers. The process tool may include support 76 on which the silicon ingot is disposed during slicing. In addition, the process tool may include slicing module 78 that is configured to slice the silicon ingot into wafers as the silicon ingot moves through the slicing module. Wafer slicing tools are generally known in the art and therefore will not be described further herein.

As the silicon ingot is pushed through the wafer slicing tool, the THz signal may be directed through the ingot in the radial direction. In particular, the system shown in FIG. 4 includes an illumination subsystem configured as described herein. In this embodiment, the illumination subsystem is configured to illuminate the silicon ingot by directing the radiation to the silicon ingot in a plane of incidence substantially parallel to a radius of the silicon ingot. For example, as shown in FIG. 4, silicon ingot 72 may have a generally cylindrical shape with axis 80 extending through the center of the silicon ingot along the length of the silicon ingot. Therefore, radius 82 of the silicon ingot is any dimension of the silicon ingot from axis 80 to side surface 84 of the silicon ingot. In one such embodiment, as shown in FIG. 4, the illumination subsystem includes radiation source 86 that is configured to direct radiation (e.g., THz radiation) to the silicon ingot. In particular, as shown in FIG. 4, radiation source 86 is configured to direct radiation to beam splitter 88, which may be configured as described herein. Radiation from radiation source 86 that passes through the beam splitter is directed to the silicon ingot in a plane of incidence that is substantially parallel to the radius of the silicon ingot. The illumination subsystem shown in the system of FIG. 4 may be further configured according to any of the embodiments described herein.

The system shown in FIG. 4 also includes a detection subsystem configured as described herein. The THz signal directed into the ingot in the radial direction as described above will transmit through the ingot, reflect from the surface, penetrate to a finite depth of the ingot then reflect or scatter. In one embodiment, the detection subsystem includes detector 90 that is configured to detect radiation transmitted through the silicon ingot. The detection subsystem may also include detector 92 that is configured to detect radiation scattered by the silicon ingot. In addition, the detection subsystem may include beam splitter 88 and detector 94 that is configured to detect radiation reflected by the silicon ingot. For example, radiation reflected by the silicon ingot may be reflected by beam splitter 88 to detector 94. The detection subsystem shown in the system of FIG. 4 may be further configured according to any of the embodiments described herein.

The system shown in FIG. 4 also includes a processor configured as described herein. For example, processor 96 may be coupled to each of the detectors shown in FIG. 4 (as shown by the dotted and dashed lines in FIG. 4) as described above such that the processor can receive output generated by each of the detectors. The processor may be configured to determine one or more characteristics of the silicon ingot as described herein. For example, the transmitted, reflected, or scattered THz signal (or some combination thereof) is detected and the wavelength(s) and its phase, amplitude, energy, intensity, or some combination thereof is characteristic of the concentration of dopants, contaminants and impurities, and the presence of voids, cracks, and other subsurface defects in the silicon ingot. In this manner, in one embodiment, the one or more characteristics determined by the processor using the output include concentration of dopants in the specimen, contaminants and impurities in the specimen, voids, cracks, and other subsurface defects in the specimen, or some combination thereof. Contaminant types may include oxygen and carbon and any other contaminants that may be present in a silicon wafer, and defects may be point, line, and volume defects and any other defects that may be present in a silicon wafer. For example, in another embodiment, the one or more characteristics include one or more characteristics of contamination in the silicon ingot, and the contamination includes oxygen contamination, carbon contamination, or some combination thereof. As used herein, the term “one or more characteristics of contamination” may include any characteristic(s) of the contamination such as whether or not the contamination is present in the specimen, number of contaminants present in the specimen, locations of contaminants present in the specimen, spatial distribution of contaminants present in the specimen, and the like. In an additional embodiment, the one or more characteristics include one or more characteristics of defects in the silicon ingot, and the defects include point defects, line defects, volume defects, or some combination thereof. The one or more characteristics of the defects may include any of the characteristics described herein. The one or more characteristics of the silicon ingot may also include any other characteristics described herein.

In some embodiments, the system shown in FIG. 4 is configured for process and quality monitoring of the manufacturing of the silicon ingot. For example, in one embodiment, processor 96 is configured to monitor a process for manufacturing the silicon ingot based on the one or more characteristics of the silicon ingot. The one or more characteristics of the silicon ingot that are used to monitor the process for manufacturing the silicon ingot may include any of the characteristics described herein. In addition, the processor may be configured to monitor the process for manufacturing the silicon ingot using any suitable technique (e.g., using a statistical process control (SPC) technique). In another embodiment, the processor is configured to monitor a quality of the silicon ingot during manufacturing of the silicon ingot based on the one or more characteristics of the silicon ingot. The quality of the silicon ingot may be determined based on any of the characteristics of the silicon ingot described herein. For example, the number of point, line, and volume defects in the silicon ingot may be used to determine the quality of the silicon ingot.

In an additional embodiment, the system is configured to determine the one or more characteristics of the silicon ingot during slicing of the silicon ingot into wafers. For example, as described above, the system may be configured to determine the one or more characteristics of the silicon ingot while the silicon ingot is disposed in a process tool such as a wafer slicing tool and during slicing of the ingot by the wafer slicing tool. In particular, as shown in FIG. 4, the system may be positioned such that the system can determine the one or more characteristics of the silicon ingot as the silicon ingot moves into the wafer slicing tool. In this manner, the one or more characteristics of the silicon ingot can be determined in situ. In addition, the one or more characteristics of the silicon ingot can be determined as a function of position across the axis of the silicon ingot due to the position of the system and the movement of the silicon ingot into the wafer slicing tool.

In one such embodiment, the processor is configured to determine start and stop points for the slicing during the slicing based on the one or more characteristics of the silicon ingot. For example, the system may be configured to use radiation in the THz range at the wafer slicing step to identify start and stop points by determining the concentration of dopants, contaminants and impurities, and detecting voids, cracks and other subsurface defects online. In one such example, the start and stop points may be identified such that portions of the silicon ingot that include contaminants, impurities, and/or defects such as those described above, unsuitable concentration(s) of dopant(s), or some combination thereof may not be sliced into wafers. In this manner, the system may be configured such that defective portions of the ingot can be rejected. In particular, the processor may determine the one or more characteristics of the silicon ingot as a function of position within the silicon ingot and across the axis of the silicon ingot. As such, the processor may determine that slicing should be stopped just before a portion of the silicon ingot that has one or more characteristics that are unsuitable would otherwise be sliced by the wafer slicing tool. In addition, the processor may determine that slicing should be started just after a portion of the silicon ingot that has one or more characteristics that are unsuitable has been moved beyond the slicing blade or blades of the wafer slicing tool. In this manner, the quality of the wafers produced by the wafer slicing process may be increased using the systems described herein.

The system may also include control subsystem 98. Control subsystem 98 may include any suitable hardware and/or software known in the art. In one embodiment, processor 96 is coupled to control subsystem 98 as described above such that the processor can send one or more characteristics of the silicon ingot determined by the processor, one or more start and/or stop points determined by the processor, or any other information described above that can be determined by the processor to the control subsystem. The control subsystem may be configured to alter one or more parameters of the process tool based on the information provided by the processor. For example, the control subsystem may be coupled to the process tool as described above such that the control subsystem can alter the one or more parameters of the process tool in response to the information about the silicon ingot or the slicing process provided by the processor. The one or more parameters of the process tool that are altered by the control subsystem may include any alterable parameter(s) of the process tool. In addition, the one or more parameters of the process tool may be altered by the control subsystem using a feedback control technique, a feedforward control technique, or an in situ control technique. For example, based upon the start and stop points determined by the processor, the control subsystem may control slicing performed by the process tool such that slicing is started and stopped at the points along the silicon ingot determined by the processor. The system shown in FIG. 4 may be further configured according to any of the embodiments described herein.

In another embodiment, the system is configured for axial monitoring of the silicon ingot. FIG. 5 illustrates one such embodiment of such a system. As shown in FIG. 5, specimen 72 includes a silicon ingot. The silicon ingot may include any silicon ingot known in the art. In some embodiments, the system may be configured to determine one or more characteristics of the silicon ingot while the silicon ingot is disposed within and/or being processed by process tool 74. Process tool 74 may be configured as described above.

As the silicon ingot is pushed through the wafer slicing tool, the THz signal is sent into the ingot along the axial direction. For example, the system shown in FIG. 5 includes an illumination subsystem configured as described herein. In this embodiment, the illumination subsystem is configured to illuminate the silicon ingot by directing the radiation to a surface of the silicon ingot that is substantially perpendicular to an axis of the silicon ingot. For example, as shown in FIG. 5, silicon ingot 72 may have a generally cylindrical shape with axis 80 extending through the center of the silicon ingot along the length of the silicon ingot. Therefore, surface 100 of the silicon ingot is substantially perpendicular to axis 80. In one such embodiment, as shown in FIG. 5, the illumination subsystem includes radiation source 102 that is configured to direct radiation (e.g., radiation in the THz range) to the silicon ingot. In particular, as shown in FIG. 5, radiation source 102 is configured to direct radiation to beam splitter 104, which may be configured as described herein. Radiation from radiation source 102 that passes through the beam splitter is directed to surface 100 of the silicon ingot. The illumination subsystem may be configured such that the radiation is directed to surface 100 at any suitable angle of incidence (e.g., a substantially normal angle of incidence or an oblique angle of incidence). The illumination subsystem shown in the system of FIG. 5 may be further configured according to any of the embodiments described herein.

The system shown in FIG. 5 also includes a detection subsystem configured as described herein. The THz signal directed into the silicon ingot will transmit through the silicon ingot, reflect from the surface, penetrate to a finite depth of the ingot then reflect or scatter. In one embodiment, the detection subsystem includes detector 106 that is configured to detect radiation transmitted through the silicon ingot. The detection subsystem may also include detector 108 that is configured to detect radiation scattered by the silicon ingot. In addition, the detection subsystem may include beam splitter 104 and detector 110 that is configured to detect radiation reflected by the silicon ingot. For example, radiation reflected by the silicon ingot may be reflected by beam splitter 104 to detector 110. The detection subsystem shown in the system of FIG. 5 may be further configured according to any of the embodiments described herein.

The system shown in FIG. 5 also includes a processor configured as described herein. For example, processor 112 may be coupled to each of the detectors shown in FIG. 5 (as shown by the dotted and dashed lines in FIG. 5) as described above such that the processor can receive output generated by each of the detectors. The processor may be configured to determine one or more characteristics of the silicon ingot as described herein. For example, the reflected or scattered THz signal (or some combination thereof) is detected by the detection subsystem and its phase, amplitude, energy, intensity, or some combination thereof is characteristic of the concentration of dopants, contaminants and impurities, and the presence of voids, cracks, and other subsurface defects in the silicon ingot. In this manner, in one embodiment, the one or more characteristics determined by the processor using the output of the detection subsystem include concentration of dopants in the specimen, contaminants and impurities in the specimen, voids, cracks, and other subsurface defects in the specimen, or some combination thereof. Contaminant types may include oxygen and carbon, and defects may be point, line, and volume defects. For example, in another embodiment, the one or more characteristics include one or more characteristics of contamination in the silicon ingot, and the contamination includes oxygen contamination, carbon contamination, or some combination thereof. In an additional embodiment, the one or more characteristics include one or more characteristics of defects in the silicon ingot, and the defects include point defects, line defects, volume defects, or some combination thereof. The one or more characteristics of the silicon ingot may include any other characteristics described herein.

In some embodiments, processor 112 is configured to monitor a process for manufacturing the silicon ingot based on the one or more characteristics of the silicon ingot. The processor may be configured to monitor the process for manufacturing the silicon ingot as described further herein. In another embodiment, the processor is configured to monitor a quality of the silicon ingot during manufacturing of the silicon ingot based on the one or more characteristics of the silicon ingot. The processor may be configured to monitor the quality of the silicon ingot during manufacturing of the silicon ingot as described further herein. In an additional embodiment, the system is configured to determine the one or more characteristics of the silicon ingot during slicing of the silicon ingot into wafers. The system may be configured to determine the one or more characteristics of the silicon ingot as described further herein. In one such embodiment, the processor is configured to determine start and stop points for the slicing during the slicing based on the one or more characteristics of the silicon ingot. The processor may be configured to determine the start and stop points as described further herein. The system shown in FIG. 5 may be further configured as described herein (e.g., according to the embodiment shown in FIG. 4 or any other embodiments described herein).

In one embodiment, the specimen includes a getter layer formed in a silicon wafer. The getter layer may include any getter layer known in the art and may be formed by any gettering process known in the art. In one such embodiment, the one or more characteristics include one or more characteristics of defects in the getter layer. The defects in the getter layer for which one or more characteristics are determined may include any defects known in the art that may be formed in or on getter layers. In this manner, the systems described herein can be configured for using radiation in the THz range to inspect the getter layer in silicon wafers. For example, the system shown in FIG. 1 may be used to inspect the getter layer in silicon wafers.

In one embodiment, the specimen includes a resist formed on a wafer. FIG. 6 illustrates one embodiment of such a specimen. In particular, the specimen shown in FIG. 6 includes resist 114 formed on wafer 116. Resist 114 may include any resist material known in the art that can be exposed at any suitable wavelength known in the art. As used herein, the term “wafer” generally refers to substrates formed of a semiconductor or non-semiconductor material. Examples of such a semiconductor or non-semiconductor material include, but are not limited to, monocrystalline silicon, gallium arsenide, and indium phosphide. Such substrates may be commonly found and/or processed in semiconductor fabrication facilities.

One or more layers may be formed upon a wafer. For example, such layers may include, but are not limited to, a resist, a dielectric material, a conductive material, and a semiconductive material. Many different types of such layers are known in the art, and the term wafer as used herein is intended to encompass a wafer on which all types of such layers may be formed.

One or more layers formed on a wafer may be patterned or unpatterned. For example, a wafer may include a plurality of dies, each having repeatable patterned features. Formation and processing of such layers of material may ultimately result in completed devices. Many different types of devices may be formed on a wafer, and the term wafer as used herein is intended to encompass a wafer on which any type of device known in the art is being fabricated.

The embodiments described herein may be configured for inspection and/or measurement of a latent image formed in a resist (e.g., a photoresist) using radiation in the THz range. Exposure of resist to electromagnetic radiation (e.g., UV light or X-rays) breaks or changes chemical bonds in the resist in a way that affects the rate of removal in subsequent process steps that selectively remove the irradiated resist (or alternatively selectively remove the unexposed resist). Measurements are needed to control the total patterning process. The preferred method today is to make measurements of the developed resist. It would be useful if measurements could be made earlier in the process or even during exposure of the resist to determine the effects of the exposure on the resist prior to development. Radiation in the THz range may be sensitive to chemical changes in the resist caused by exposure or subsequent process steps (e.g., heat treatment or post exposure bake) and provide useful information to control the process steps without damaging the resist (e.g., since the energy of radiation in the THz range is relatively low and the resist is not sensitive to radiation in the THz range). One example of a way this information could be used to control process steps is to improve the gate linewidth which determines transistor speed.

In one embodiment, the resist has been exposed in an exposure process. For example, after exposure, substantially the entire resist-coated substrate surface may include both exposed and unexposed regions. For example, as shown in FIG. 7, portion 118 of the resist formed on wafer 116 may be exposed to electromagnetic radiation 120. The portion of the resist may be exposed to any suitable electromagnetic radiation using any suitable exposure system. Therefore, portion 118 of the resist forms an exposed region of the resist. In one embodiment, a latent image is formed in the resist. For example, a latent image may be formed in the exposed region of the resist. Portion 122 of the resist may not be exposed to the electromagnetic radiation. Therefore, portion 122 of the resist forms ar unexposed region of the wafer and will not have a latent image formed therein.

FIG. 8 illustrates one embodiment of a system configured to determine one or more characteristics of the specimen shown in FIG. 7. In particular, the system shown in FIG. 8 includes an illumination subsystem that is configured to illuminate the specimen with radiation in the THz range. For example, the illumination subsystem includes radiation source 124, which is configured to generate radiation in the THz range. The radiation source may include any such radiation source described herein. The radiation source is configured to direct the radiation to the specimen as shown in FIG. 8. For example, the radiation source may be configured to direct the radiation to the specimen at an oblique angle of incidence, which may include any suitable oblique angle of incidence known in the art. Alternatively, the radiation source may be configured to direct the radiation to the specimen at a substantially normal angle of incidence.

The illumination subsystem may be configured to illuminate exposed and unexposed regions of the resist with radiation. For example, the illumination subsystem may be configured as described further herein such that the illumination subsystem can scan the radiation across the exposed and unexposed regions of the resist and/or change the position on the resist that is illuminated with the radiation. In this manner, after exposure, substantially the entire resist coated substrate surface, both the exposed and unexposed regions, are illuminated with radiation in the THz range. The illumination subsystem of the system shown in FIG. 8 may be further configured according to any of the embodiments described herein.

The system shown in FIG. 8 also includes a detection subsystem configured to detect radiation propagating from the specimen in response to illumination of the specimen and to generate output responsive to the detected radiation, which includes radiation in the THz range. The detection subsystem includes detector 126 that is configured to detect light transmitted through the specimen. The detection subsystem also includes detector 128 that is configured to detect light reflected by the specimen. In addition, the detection subsystem includes detector 130 that is configured to detect light scattered by the specimen. In this manner, the THz signal that is transmitted, reflected, and/or scattered by the exposed and unexposed regions of the resist may be detected. The detection subsystem included in the system shown in FIG. 8 may be further configured as described herein.

The system shown in FIG. 8 also includes a processor configured to determine the one or more characteristics of the specimen using the output. For example, the system includes processor 132 that is coupled to the detectors of the detection subsystem as described herein such that the processor can receive output generated by the detectors. The processor may be configured to determine the one or more characteristics of the specimen using the output as described further herein. In one embodiment, the one or more characteristics include a characteristic of one or more chemical changes in the resist. For example, the phase, amplitude, energy, intensity, or some combination thereof of the transmitted, reflected and/or scattered THz signal are characteristic of the chemical changes (or lack thereof) in the resist and can therefore be used by the processor to determine a characteristic of the chemical changes. In another embodiment, the one or more characteristics include a characteristic of one or more chemical changes in the resist as a function of position on the wafer. In an additional embodiment, the one or more characteristics include a characteristic of one or more chemical changes in the resist, and the processor is configured to determine one or more variations in exposure of the resist based on the characteristic of the one or more chemical changes in the resist. For example, variations in the chemical changes are a result of exposure variations such as variations in resist thickness, substrate alignment, exposure time, exposure temperatures, laser intensity, etc. and can therefore be used by the processor to determine such variations in the exposure process. The processor of the system shown in FIG. 8 can be further configured as described herein (e.g., according to any other embodiments described herein).

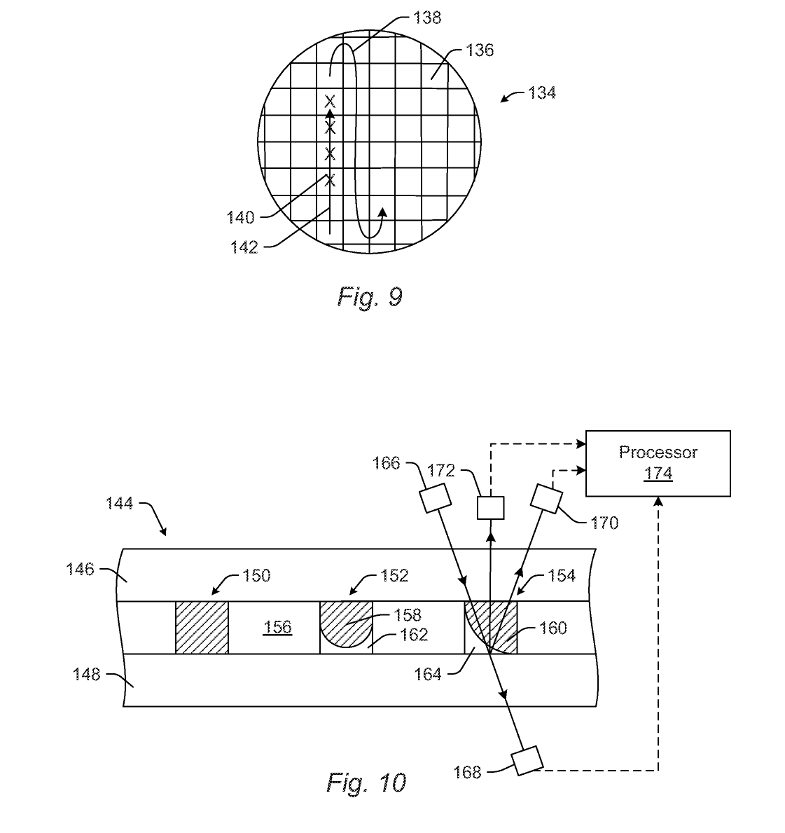

In one embodiment, the operation of the system described above can be repeated over substantially the entire substrate surface (e.g., in a raster fashion) to allow mapping of the THz signal (indicative of the chemical changes) as a function of x and y position. In this manner, the system can be used to inspect substantially the entire wafer in a raster fashion. This THz raster type inspection can follow the raster movement of the exposure process. For example, FIG. 9 illustrates one embodiment of an upper surface of specimen 134 that includes a resist formed on a wafer. As shown in FIG. 9, the exposure process may expose dies 136 on the wafer in a raster fashion following exposure path 138. The system shown in FIG. 8 may be configured to determine the one or more characteristics of the resist (including exposed and unexposed regions of the resist) at positions 140 along path 142. In this manner, the system may determine the one or more characteristics of the resist along the same path in which the resist was exposed. The system may be configured such that the one or more characteristics of the resist can be determined at positions 140 along path 142 during exposure of the resist or subsequent to exposure of the resist. The system shown in FIG. 8 may be further configured as described herein.

In one embodiment, the specimen includes a printed circuit board (PCB) in which vias are formed. One embodiment of such a specimen is shown in FIG. 10. PCBs include multiple layers connected through metal connectors called vias. For example, as shown in FIG. 10, PCB 144 includes organic dielectric layers 146 and 148, which may be formed of any suitable material using any suitable process known in the art. Metal vias 150, 152, and 154 are formed between layers 146 and 148 in another dielectric layer 156. Although only three vias are shown in FIG. 10, it is to be understood that any suitable number of metal vias may be formed in the PCB. Typical dimensions of a via may be about 60 microns in upper diameter, about 45 microns in bottom diameter, and about 30 microns in depth. As shown in FIG. 10, metal vias 152 and 154 are incompletely filled with metal 158 and 160, respectively, which leads to voids 162 and 164, respectively, or dimples in the metal vias. Incomplete metal filling of these vias makes PCBs function improperly.

Although many PCB manufacturers share this manufacturing challenge, today there is no analytical inspection solution to this problem. Similar challenges exist in the manufacturing of semiconductors, but critical dimensions (CDs) in semiconductors are several orders of magnitude smaller. The embodiments described herein may be used to detect such buried voids and dimples in vias in PCBs. In this manner, the embodiments described herein may be configured and used for inspection of PCBs using radiation in the THz range. For example, FIG. 10 illustrates one embodiment of a system that is configured to determine one or more characteristics of PCB 144.

The system shown in FIG. 10 includes an illumination subsystem configured to illuminate the PCB with radiation. For example, the illumination subsystem includes radiation source 166 that is configured to illuminate the PCB with radiation. In addition, the illumination subsystem may be configured to illuminate the PCB with radiation in the THz range. The illumination subsystem may be further configured according to any of the embodiments described herein.

The system shown in FIG. 10 also includes a detection subsystem configured to detect radiation propagating from the PCB in response to illumination of the PCB and to generate output responsive to the detected radiation. The detected radiation includes radiation in the THz range. For example, the detection subsystem includes detector 168 configured to detect radiation transmitted by the PCB. The detection subsystem also includes detector 170 configured to detect radiation reflected by the PCB. In addition, the detection subsystem includes detector 172 configured to detect radiation scattered from the PCB. In this manner, the detection subsystem may be configured to detect the transmitted, reflected, and/or scattered THz signal (or some combination thereof). The detectors and the detection subsystem may be further configured according to any of the embodiments described herein.

The system shown in FIG. 10 also includes a processor configured to determine the one or more characteristics of the PCB using the output. For example, the system includes processor 174 that is coupled to detectors 168, 170, and 172 as described herein such that the processor can receive the output generated by the detectors. In one embodiment, the one or more characteristics include one or more characteristics of defects in the vias. In another embodiment, the one or more characteristics include one or more characteristics of subsurface defects in the vias. For example, the phase, amplitude, energy, and/or intensity (or some combination thereof) of the transmitted, reflected, and/or scattered THz signals (or some combination thereof) are characteristic of the presence of buried voids and dimples and may therefore be used by the processor to determine the one or more characteristics of defects and/or subsurface defects in the vias. The operation of the system described above may be repeated over substantially the entire microvia board (e.g., in a raster fashion) to allow mapping of the THz signal (indicative of the presence of buried voids and dimples) as a function of x and y position. In this manner, in some embodiments, the one or more characteristics include one or more characteristics of defects in the vias as a function of position on the PCB. The processor may be configured to determine any of the characteristics of the PCB as described further herein. The processor may be further configured according to any of the embodiments described herein. In addition, the system shown in FIG. 10 may be further configured as described herein.

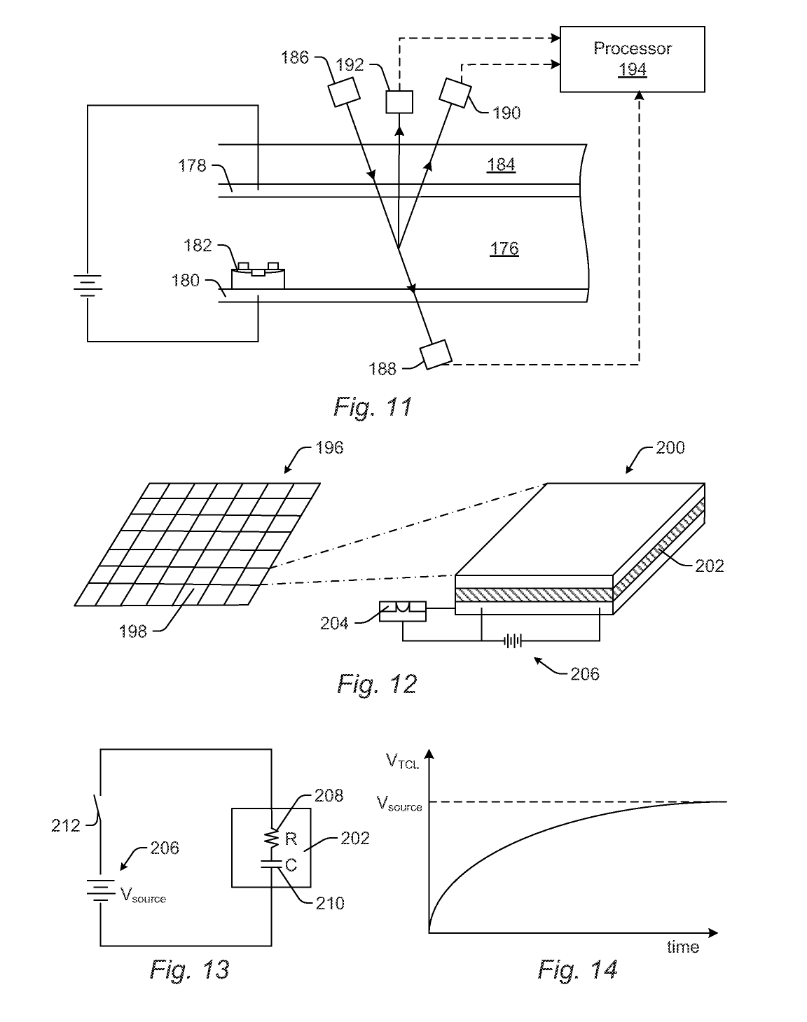

In one embodiment, the specimen includes a flat panel display (FPD). One embodiment of such a specimen is illustrated in FIG. 11. As shown in FIG. 11, the FPD includes liquid crystal (LC) 176 positioned between polarizers 178 and 180 that are oriented at 90 degrees to each other. An electric field across the LC layer (e.g., an electric field applied to transistor 182) causes a dipole switching, making the device appear clear. With color filters such as color filter 184, this on-command clear or dark switching is used to generate red, green, and blue colors. Today, testing of these devices is performed by using electron beams to measure electrical properties. In addition, 100% interrogation of the devices is needed. However, electron beam testing is slow and costly.

FIG. 11 illustrates one embodiment of a system configured to determine one or more characteristics of a FPD. As described further herein, the system can be used for detection of defects in FPDs. In particular, radiation in the THz range is sensitive to dipole changes in materials, making it potentially ideal for use in an FPD inspection system. In addition, inspection of FPDs using radiation in the THz range may be used to detect defects before final assembly and thus may allow re-working of defective products.

The system shown in FIG. 11 includes an illumination subsystem configured to illuminate the specimen with radiation. For example, the illumination subsystem includes radiation source 186 that is configured to illuminate the specimen with radiation. In particular, radiation source 186 may be configured to illuminate a cell (not shown in FIG. 11) of the FPD with radiation in the THz range. Radiation source 186 may include any of the radiation sources described herein. As shown in FIG. 11, the radiation source may be configured to direct the radiation to the FPD at an oblique angle of incidence, which may include any suitable oblique angle of incidence. Alternatively, the radiation source and/or the illumination subsystem may be configured to direct the radiation to the FPD at a substantially normal angle of incidence. The illumination subsystem may be further configured as described herein.

The system shown in FIG. 11 also includes a detection subsystem configured to detect radiation propagating from the specimen in response to illumination of the specimen and to generate output that is responsive to the detected radiation. The detected radiation includes radiation in the THz range. As shown in FIG. 11, the detection subsystem includes detector 188 configured to detect radiation transmitted through the FPD. The detection subsystem also includes detector 190 configured to detect radiation reflected by the FPD. In addition, the detection subsystem includes detector 192 configured to detect radiation scattered by the FPD. In this manner, the detection subsystem may be configured to detect the transmitted, reflected, and/or scattered THz signal (or some combination thereof). The detectors and the detection subsystem may be further configured as described herein.

The system shown in FIG. 11 also includes a processor that is configured to determine the one or more characteristics of the specimen using the output. For example, as shown in FIG. 11, the system includes processor 194 that is configured to determine the one or more characteristics of the specimen using the output. Processor 194 may be coupled to each of the detectors as described above such that the processor can receive the output generated by the detectors and can thereby use the output to determine the one or more characteristics of the FPD. In one embodiment, the one or more characteristics include one or more characteristics of defects in the FPD. The processor may be further configured as described herein.

In one embodiment, the system is configured to apply an electric field across a LC layer of the FPD. The system may be configured to apply the electric field across the LC layer in any suitable manner. In one such embodiment, the detection subsystem is configured to detect the radiation before and after the electric field is applied to the LC layer. The processor is configured to determine changes in the detected radiation before and after the electric field is applied to the LC layer. The processor is also configured to determine the one or more characteristics based on the changes, and the one or more characteristics include functionality of a FPD cell formed by the LC layer. In this manner, the system may be configured to apply an electric field across the LC layer and observe the changes in phase, amplitude, energy and/or intensity (or some combination thereof) of the transmitted, reflected, and/or scattered THz signal (or some combination thereof). These changes are characteristic of the functionality of the FPD cell and can, therefore, be used by the processor to determine the functionality of the FPD cell.

In another embodiment, the one or more characteristics include functionality of cells in the FPD as a function of position across the FPD. For example, the operation of the system described above may be repeated over substantially the entire FPD (e.g., in a raster fashion) to allowing mapping of the THz signal (indicative of the functionality of the FPD cell) as a function of x and y position. The system may be configured to repeat this operation as described further herein. The system shown in FIG. 11 may be further configured as described herein.

In this manner, the systems described herein may be configured for inspection and/or metrology of FPDs, liquid crystal displays (LCDs), and other similar devices using radiation in the THz range. In some embodiments in which the specimen includes a FPD, the one or more characteristics include voltage build-up behavior of a transparent conductive layer (TCL) formed within pixels of the FPD. In another such embodiment, the illumination subsystem is configured to illuminate the FPD using a non-contact technique, and the detection subsystem is configured to detect the radiation propagating from the FPD using a non-contact technique. In one embodiment, the specimen includes a LCD. In one such embodiment, the one or more characteristics include voltage build-up behavior of a TCL formed within pixels of the LCD. In another such embodiment, the illumination subsystem is configured to illuminate the LCD using a non-contact technique, and the detection subsystem is configured to detect the radiation propagating from the LCD using a non-contact technique. In this manner, the embodiments described above make use of electromagnetic radiation in the THz range (about 0.1 THz to about 10 THz) for metrology and inspection applications in the manufacturing of FPDs, LCDs, and other similar products. By using radiation in the THz range, electrical and other properties can be detected and measured without contact.

As shown in FIG. 12, specimen 196 such as a FPD, LCD, and/or other similar product is made of individual pixels 198. As shown by pixel 200 in FIG. 12, within each pixel, there is a layer of TCL 202 such as indium tin oxide (ITO). A relatively small transistor (e.g., transistor 204) is connected to each pixel controlling the on- and off-switching of the pixel. Both the transistor and the pixel are connected to an external voltage source (e.g., external voltage source 206). The system may be configured such that an external voltage can be applied across the TCL. For example, one end of the external voltage source may be connected to the top layer, and the other end of the external voltage source may be connected to the bottom layer.

FIG. 13 illustrates an engineering schematic of a single pixel. In this illustration, TCL 202 is represented by resistor 208 and capacitor 210, and the transistor is represented by on-and-off switch 212 connected to external voltage source 206, V_{source}. When the switch is closed or turned on, the voltage will ramp up on the TCL. The ramp-up rate is determined by the resistivity and capacitance of the TCL material. In other words, the ramp-up rate is a function of the resistance and capacitance (e.g., =f(R, C)). The voltage on the TCL will eventually reach the voltage of the external source, V_{source}, as shown in FIG. 14 in which the voltage of the TCL, V_{TCL}, is plotted as a function of time.

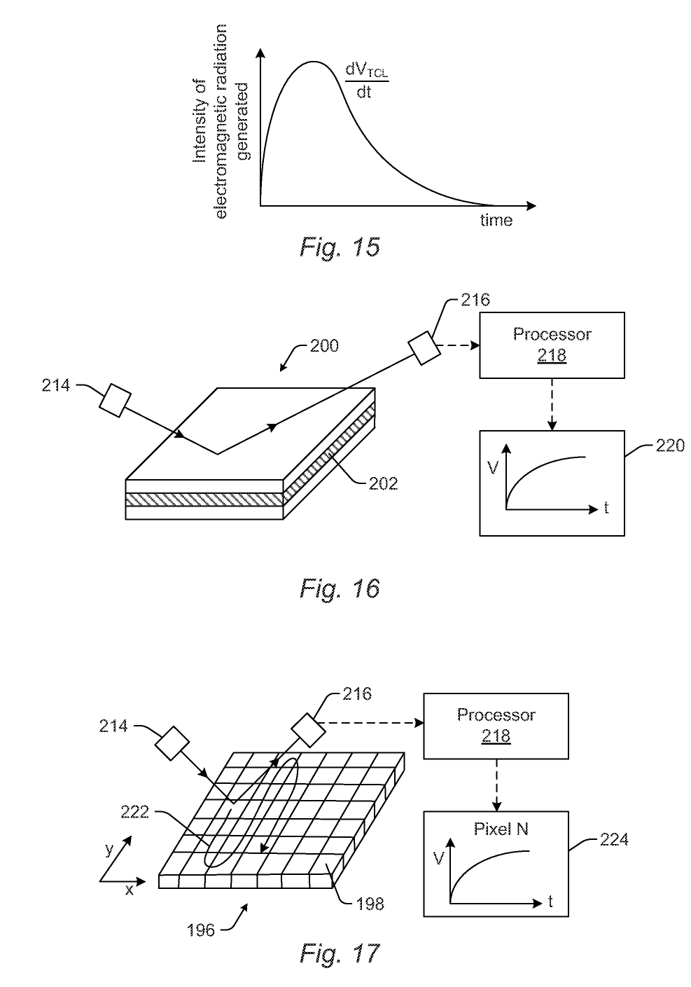

When radiation is directed onto the TCL during the voltage ramp-up, charge-carriers will be generated. The voltage difference across the TCL and the source will then accelerate these carriers. This acceleration of the carriers generates electromagnetic radiation in the THz range, whose characteristics can be determined by the first time derivative of the TCL's voltage ramp up curve, as shown in FIG. 15. By detecting this radiation in the THz range, the voltage build-up behavior of the TCL can be measured.

FIG. 16 illustrates one embodiment of a system configured to determine one or more characteristics of a specimen including the voltage build-up behavior of the TCL of an FPD, LCD, or other similar product. In particular, the system includes an illumination subsystem configured to illuminate the specimen with radiation. As shown in FIG. 16, the illumination subsystem includes radiation source 214 configured to direct radiation to pixel 200. The radiation source may include any of the radiation sources described herein. For example, the radiation source may include a light source such as a laser. The radiation directed to pixel 200 preferably includes excitation light. As shown in FIG. 16, the radiation source is configured to direct the radiation to the pixel at an oblique angle of incidence, which may include any suitable oblique angle of incidence. However, the radiation source and/or the illumination subsystem may be configured to direct the radiation to the pixel at a substantially normal angle of incidence. The illumination subsystem of the system shown in FIG. 16 may be further configured as described herein.

The system also includes a detection subsystem configured to detect radiation propagating from the specimen in response to illumination of the specimen and to generate output responsive to the detected radiation. The detected radiation includes radiation in the THz range. For example, the detection subsystem includes detector 216 configured to detect radiation in the THz range propagating from pixel 200. The detector may include any suitable THz radiation detector. The radiation that is detected by the detector may include radiation scattered by the pixel and/or radiation reflected by the pixel. The detection subsystem of the system shown in FIG. 16 may be further configured as described herein.

The system also includes a processor configured to determine the one or more characteristics of the specimen using the output. For example, the system may include processor 218 that is configured to determine one or more characteristics of pixel 200 using output generated by detector 216 of the detection subsystem. As shown in FIG. 16, the processor may use the output generated by the detector to generate voltage ramp-up curve 220 for the TCL. The processor may use the voltage ramp-up curve to determine the voltage build-up behavior of the TCL as described further above.

Substantially an entire FPD, LCD, and/or other similar product can be examined by moving the FPD, LCD, and/or other similar product (e.g., in a raster fashion) in the x and y directions relative to the radiation source and the THz radiation detector. For example, as shown in FIG. 17, the illumination subsystem may be configured such that radiation from radiation source 214 can scan over pixels 198 of specimen 196 such as a FPD, LCD, and/or other similar product in path 222. The illumination subsystem or the system may be configured to scan radiation from radiation source 214 over the pixels as described further herein. For example, the system may include a specimen handler (not shown) that moves the specimen relative to the radiation source and the THz detector. The detection subsystem may also be configured such that detector 216 detects radiation propagating from the specimen along path 222 in response to the illumination scanned along path 222. The detection subsystem may be configured to detect the radiation in this manner as described further herein. In addition, although the system may raster scan the specimen in the x and y directions, as shown in FIG. 17, it is to be understood that the system may scan the specimen in any other suitable manner. In this embodiment, processor 218 may be configured to use the output generated by the detector to generate voltage ramp-up curve 224 for the TCL of each individual pixel (e.g., Pixel N) of the specimen. The processor may use the voltage ramp-up curve to determine the voltage build-up behavior of the TCL of each individual pixel of the specimen as described further above.

The embodiments described above for determining one or more characteristics of FPDs, LCDs, and other similar products have a number of advantages over other metrology and inspection systems for such products. For example, the systems described above require no contact with the specimen thereby preventing potential damage to the specimen. In addition, inspection and metrology performed using radiation in the THz range can be performed substantially quickly compared to traditional electron beam measurement and inspection techniques. Furthermore, radiation in the THz range is the last bit of the electromagnetic spectrum that has not been available for commercial uses. However, this range of THz radiation brings as much promise as other ranges in the electromagnetic spectrum such as microwave, infrared, and X-ray. With the deeper penetration power and non-ionizing nature of radiation in the THz range, THz signals will open new inspection possibilities that are unique relative to other techniques. Embodiments described herein for determining one or more characteristics of other specimens described herein have all of the advantages described above.

In one embodiment, the specimen includes a solar cell panel. For example, specimen 16 shown in FIG. 1 may be a solar cell panel, and the system shown in FIG. 1 may be configured as described above to determine one or more characteristics of the solar cell panel. For example, the illumination subsystem may be configured to illuminate the solar cell panel with radiation in the THz range as described above. In addition, the detection subsystem may be configured to detect the transmitted, reflected, and/or scattered THz signal (or some combination thereof) as described above.

In one embodiment, the one or more characteristics include carrier concentration in the solar cell panel. For example, the phase, amplitude, energy, and/or intensity (or some combination thereof) of the transmitted, reflected, and/or scattered THz signal (or some combination thereof) are characteristic of the local concentration of carriers in the solar cell panel and can therefore be used by the processor to determine the carrier concentration in the solar cell panel. In another embodiment, the one or more characteristics include carrier lifetime in the solar cell panel. In addition, the system may be configured to determine carrier concentration and lifetime in solar cell panels using radiation in the THz range.

In an additional embodiment, the one or more characteristics include the one or more characteristics as a function of position across the solar cell panel. The system shown in FIG. 1 may be configured to determine the one or more characteristics of the solar cell panel as a function of position as described further above. For example, the system shown in FIG. 1 may be configured to repeat the operation of the system over substantially the entire solar cell panel surface (e.g., in a raster fashion) to allow mapping of the THz signal (indicative of the local carrier concentration) as a function of x and y position on the solar cell panel.

In some embodiments, the specimen includes a low k dielectric material formed on a substrate. For example, such a specimen may be configured as shown in FIG. 6 with resist 114 replaced by a low k dielectric material. In one such embodiment, the low k dielectric material may be formed on wafer 116 as shown in FIG. 6. However, wafer 116 may be replaced with any other suitable substrate. The low k dielectric material may be formed on the substrate using any suitable process known in the art. As used herein, the term “low k dielectric material” is generally defined as any material having a dielectric constant of less than about 3.9, where “k” refers to the real part of the dielectric constant as measured at electrical frequencies.

The system shown in FIG. 1 may be used to determine the one or more characteristics of the low k dielectric material. For example, the illumination subsystem of the system shown in FIG. 1 may be configured to illuminate the low k material with radiation in the THz range. In addition, the detection subsystem is configured to detect the transmitted, reflected, and/or scattered THz signal (or some combination thereof).

In one embodiment, the one or more characteristics include one or more characteristics of porosity, delamination, composition of one or more elements in the dielectric material, or some combination thereof; In this manner, the system may be configured to determine porosity, delamination, and composition of oxygen and/or hydrogen in low k dielectric materials using radiation in the THz range. For example, the phase, amplitude, energy, and/or intensity (or some combination thereof) of the transmitted, reflected, and/or scattered THz signal (or some combination thereof) are characteristic of porosity, delamination, and composition of oxygen and hydrogen in low k materials and can therefore be used by the processor to determine the one or more characteristics of the low k material described above. In a similar manner, the system may be configured to determine one or more characteristics (composition, distribution, etc.) of any other elements and/or molecules present in the low k dielectric material such as nitrogen.

In another embodiment, the one or more characteristics include the one or more characteristics as a function of position on the low k dielectric material. The system may be configured to determine the one or more characteristics of the low k dielectric material as a function of position as described above. For example, the system may be configured to repeat the operation of the system described above over substantially the entire low k material surface (e.g., in a raster fashion) to allow mapping of the THz signal (indicative of porosity, delamination, and composition of oxygen and/or hydrogen) as a function of x and y position on the low k dielectric material.

In some embodiments, the specimen includes a layer of borophosphosilicate glass (BPSG) formed on a substrate. For example, such a specimen may be configured as shown in FIG. 6 with resist 114 replaced by a layer of BPSG. In one such embodiment, the layer of BPSG may be formed on wafer 116 as shown in FIG. 6. However, wafer 116 may be replaced with any other suitable substrate. The layer of BPSG may be formed on the substrate using any suitable process known in the art.

The system shown in FIG. 1 may be used to determine the one or more characteristics of the layer of BPSG. For example, the illumination subsystem of the system shown in FIG. 1 may be configured to illuminate the layer of BPSG with radiation in the THz range as described above. In addition, the detection subsystem of the system shown in FIG. 1 may be configured to detect the transmitted, reflected, and/or scattered THz signal (or some combination thereof) as described above.

In one embodiment, the one or more characteristics include concentration of boron in the layer, concentration of phosphorus in the layer, or some combination thereof. For example, the phase, amplitude, energy, and/or intensity (or some combination thereof) of the transmitted, reflected, and/or scattered THz signal (or some combination thereof) are characteristic of the boron and phosphorus concentration in the layer of BPSG and can therefore be used by the processor to determine the boron and/or phosphorus concentration in the layer of BPSG. In this manner, the system may be configured to determine the boron and/or phosphorus concentration in a layer of BPSG using radiation in the THz range.

In another embodiment, the one or more characteristics include the one or more characteristics of the layer of BPSG as a function of position on the layer. The system may be configured to determine the one or more characteristics of the layer of BPSG as a function of position as described above. For example, the system may be configured to repeat the operation of the system described above over substantially the entire surface of the layer of BPSG (e.g., in a raster fashion) to allow mapping of the THz signal (indicative of boron and phosphorus concentration) as a function of x and y position on the layer of BPSG.

In some embodiments, the specimen includes gallium nitride (GaN). For example, such a specimen may be configured as shown in FIG. 6 with resist 114 replaced by GaN. In one such embodiment, the (GaN may be formed on wafer 116 as shown in FIG. 6. However, wafer 116 may be replaced with any other suitable substrate. The layer of GaN may be formed on the substrate using any suitable process known in the art. In another such example, such a specimen may be configured as shown in FIG. 1 with specimen 16 configured as a substrate formed of GaN.

The system shown in FIG. 1 may be used to determine the one or more characteristics of the GaN. For example, the illumination subsystem of the system shown in FIG. 1 may be configured to illuminate the (CaN with radiation in the THz range as described above. In addition, the detection subsystem of the system shown in FIG. 1 may be configured to detect the transmitted, reflected, and/or scattered THz signal (or some combination thereof) from the GaN as described above.

In one embodiment, the one or more characteristics include concentration of the GaN, content distribution of the GaN, or some combination thereof. For example, the phase, amplitude, energy, and/or intensity (or some combination thereof) of the transmitted, reflected, and/or scattered THz signal (or some combination thereof) are characteristic of the concentration and content distribution of the GaN and can therefore be used by the processor to determine the concentration and/or content distribution of the GaN. In another embodiment, the system is configured to determine the one or more characteristics of the GaN during a process performed for the GaN. For example, the system may be configured to determine the concentration and/or content distribution of GaN using radiation in the TH-z range during the manufacturing (e.g., growing and/or treating) of GaN materials. In an additional embodiment, the one or more characteristics include the one or more characteristics as a function of position on the GaN. For example, the system may be configured to repeat the operation of the system over substantially the entire GaN surface (e.g., in a raster fashion) to allow mapping of the THz signal (indicative of GaN concentration) as a function of x and y position. In one embodiment in which the one or more characteristics include the one or more characteristics as a function of position on the GaN, the processor is configured to monitor or control a GaN manufacturing process based on the one or more characteristics as a function of the position on the GaN. For example, the mapped information that may be generated as described above can be used for improving and better-controlling the GaN manufacturing process.

In one embodiment, the specimen includes a material grown in a substrate during a metal organic chemical vapor deposition (MOCVD) process. For example, such a specimen may be configured as shown in FIG. 6 with resist 114 replaced by a material grown in the substrate during a MOCVD process. In one such embodiment, the material may be grown in wafer 116 as shown in FIG. 6. However, wafer 116 may be replaced with any other suitable substrate. The MOCVD process may include any suitable process known in the art.

The system shown in FIG. 1 may be used to determine the one or more characteristics of the material. For example, the illumination subsystem of the system shown in FIG. 1 may be configured to illuminate the material with radiation in the THz range as described above. In addition, the detection subsystem of the system shown in FIG. 1 may be configured to detect the transmitted, reflected, and/or scattered THz signal (or some combination thereof) from the material as described above.

In one such embodiment, the one or more characteristics include concentration of the material in the substrate. For example, the phase, amplitude, energy, and/or intensity (or some combination thereof) of the transmitted, reflected, and/or scattered THz signal (or some combination thereof) are characteristic of the concentration of grown materials in substrates and can therefore be used by the processor to determine the concentration of the material. In this manner, the system may be configured to determine the concentration of materials grown in substrates in the MOCVD process using radiation in the THz range. In another embodiment, the one or more characteristics include the one or more characteristics as a function of position across the substrate. For example, the system may be configured to perform the operation of the system over substantially the entire substrate surface (e.g., in a raster fashion) to allow mapping of the THz signal (indicative of concentration of grown materials) as a function of x and y position. In one embodiment in which the one or more characteristics include the one or more characteristics as a function of position across the substrate, the processor is configured to monitor or control the MOCVD process based on the one or more characteristics as the function of the position across the substrate. For example, the mapping information generated as described above can be used for improving and better-controlling the MOCVD process.

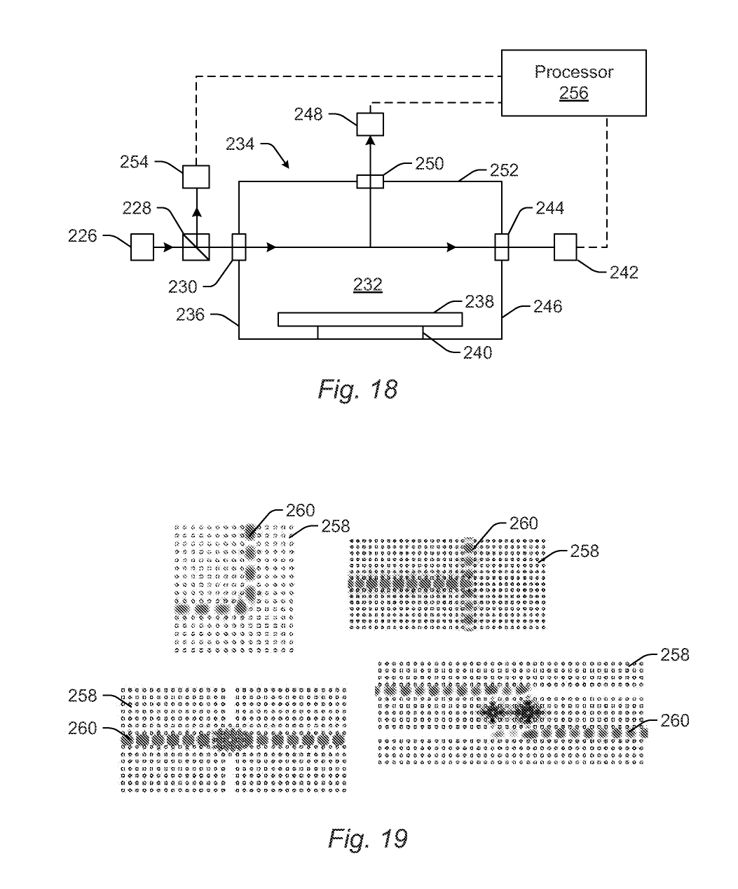

Another embodiment relates to a different system configured to determine one or more characteristics of one or more chemical vapors, one or more deposited materials, or some combination thereof in a chamber of a MOCVD reactor. One such embodiment is shown in FIG. 18. This system includes an illumination subsystem configured to illuminate an interior of the chamber of the MOCVD reactor. The illumination subsystem may be configured to illuminate the interior of the chamber with radiation in the THz range. For example, the illumination subsystem includes radiation source 226 that is configured to direct radiation (e.g., radiation in the THz range) through beam splitter 228 and window 230 into interior 232 of chamber 234 of a MOCVD reactor (not shown). Radiation source 226 and beam splitter 228 may be further configured as described herein. Window 230 may be formed of any suitable material and may be formed in wall 236 of chamber 234 in any suitable manner. Alternatively, the illumination subsystem may be configured to direct the radiation through wall 236, and in such instances, window 230 may not be formed in wall 236. Chamber 234 and the MOCVD reactor may have any suitable configuration known in the art. As shown in FIG. 18, specimen 238 may be disposed in the interior of the chamber (e.g., on support 240) during a process performed in chamber 234. Support 240 may have any suitable configuration known in the art. Specimen 238 may be further configured as described herein. In particular, in the embodiment shown in FIG. 18, the specimen includes one or more materials deposited or grown in a substrate during a MOCVD process performed in the chamber. In addition, the illumination subsystem of the system shown in FIG. 18 may be further configured as described herein.

The system also includes a detection subsystem configured to detect radiation propagating from the interior of the chamber in response to illumination of the interior of the chamber and to generate output responsive to the detected radiation. The detected radiation includes radiation in the THz range. In one embodiment, the detected radiation includes reflected radiation, transmitted radiation, scattered radiation, or some combination thereof. In this manner, the detection subsystem may be configured to detect the transmitted, reflected, and/or scattered THz signal (or some combination thereof). For example, as shown in FIG. 18, the detection subsystem includes detector 242 configured to detect light transmitted through interior 232 and through window 244 disposed in wall 246 of chamber 234. Window 244 may be configured as described above. In addition, detector 242 may be configured to detect the light transmitted through interior 232 and wall 246, and in such instances window 244 may not be formed in wall 246. Detector 242 may be further configured as described herein.

The detection subsystem also includes detector 248 configured to detect light scattered by interior 232 and transmitted through window 250 disposed in wall 252 of chamber 234. Window 250 may be configured as described above. In addition, detector 248 may be configured to detect the light scattered by interior 232 and transmitted by wall 252, and in such instances window 250 may not be formed in wall 252. Detector 248 may be further configured as described herein.

The detection subsystem also includes detector 254 configured to detect light reflected by interior 232, transmitted by window 230, and reflected by beam splitter 228. In addition, detector 254 may be configured to detect the light reflected by interior 232 and transmitted by wall 236, and in such instances window 230 may not be formed in wall 236. Detector 254 may be further configured as described herein. The detection subsystem shown in FIG. 18 may be further configured as described herein.

The system shown in FIG. 18 also includes processor 256 configured to determine one or more characteristics of the one or more chemical vapors, the one or more deposited materials, or some combination thereof in the chamber of the MOCVD reactor using the output. The processor may be coupled to detectors 242, 248, and 254 as described further herein such that the processor can receive the output generated by the detectors of the detection subsystem and use the output to determine the one or more characteristics of the one or more chemical vapors, the one or more deposited materials, or some combination thereof in the chamber. The processor may be configured to determine the one or more characteristics of the one or more chemical vapors, the one or more deposited materials, or some combination thereof in the chamber as described further herein.

For example, in one embodiment, the output generated by the detection subsystem is responsive to a wavelength, phase, amplitude, energy, intensity, or some combination thereof of the detected radiation, and the processor is configured to determine the one or more characteristics of the one or more chemical vapors, the one or more deposited materials, or some combination thereof in the chamber using the wavelength, phase, amplitude, energy, intensity, or some combination thereof of the detected radiation. In one embodiment, the one or more characteristics of the one or more chemical vapors, the one or more deposited materials, or some combination thereof in the chamber include vapor content of the one or more chemical vapors, the one or more deposited materials, or some combination thereof in the chamber. For example, the phase, amplitude, energy, and/or intensity (or some combination thereof) of the transmitted, reflected, and/or scattered THz signal (or some combination thereof) are characteristic of vapor content in the chamber and can, therefore, be used by the processor to determine the vapor content of the one or more chemical vapors, the one or more deposited materials, or some combination thereof in the chamber. In this manner, the system shown in FIG. 18 may be configured to determine the vapor content of the one or more chemical vapors, the one or more deposited materials, or some combination thereof in the chamber of a MOCVD process using radiation in the THz range.

In one embodiment in which the one or more characteristics of the one or more chemical vapors, the one or more deposited materials, or some combination thereof in the chamber include vapor content, the processor is configured to monitor or control the MOCVD process based on the vapor content. For example, the vapor content information described above may be used to control the MOCVD process. The processor may be further configured according to any other embodiments described herein. In addition, the system shown in FIG. 18 may be further configured as described herein (e.g., according to any other embodiments described herein).

Another embodiment relates to a method for determining one or more characteristics of a specimen. The specimen may include any of the specimens described herein. The method includes illuminating the specimen with radiation. Illuminating the specimen with radiation may be performed as described further herein. The radiation may include any of the radiation described herein (e.g., radiation in the UV range, radiation in the THz range, radiation in the visible range, radiation in the IR range, or some combination thereof).

The method also includes detecting radiation propagating from the specimen in response to the illuminating step to generate output responsive to the detected radiation. The detected radiation includes radiation in the THz range. The radiation propagating from the specimen may include any of the radiation described herein (e.g., radiation transmitted by the specimen, radiation scattered from the specimen, radiation reflected by the specimen, or some combination thereof). The radiation may be detected as described further herein. The output may include any of the output described herein.

The method further includes determining the one or more characteristics of the specimen using the output. The one or more characteristics of the specimen may include any of the characteristic(s) described herein. The one or more characteristics of the specimen may be determined according to any of the embodiments described herein.

Each of the embodiments of the method described above may include any other step(s) described herein. Furthermore, each of the embodiments of the method described above may be performed by any of the systems described herein.

All of the methods described herein may include storing results of one or more steps of the method embodiments in a storage medium. The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc. For example, after the method determines the one or more characteristics of the specimen, the method may include storing the determined characteristic(s) in a storage medium. Furthermore, the results may be stored “permanently,” “semi-permanently,” temporarily, or for some period of time. For example, the storage medium may be random access memory (RAM), and the results may not necessarily persist indefinitely in the storage medium. In a similar manner, any of the embodiments of the systems described herein may be configured to store any of the results described herein in a storage medium as described above. Storing the results may be performed by any of the processors described herein.

The embodiments described herein have a number of advantages over other methods and systems for determining characteristic(s) of a specimen. For example, radiation in the THz range behaves dramatically differently than radiation in other ranges currently used in inspection and metrology systems today. In particular, radiation in the THz range has deeper penetration power and a non-ionizing nature relative to other inspection technologies, which is particularly advantageous for determining the characteristics described herein for the specimens described herein. In addition, radiation in the THz range is the last bit of the electromagnetic spectrum that has not been available for commercial uses. However, this range of THz radiation brings as much promise as other ranges in the electromagnetic spectrum such as microwave, infrared, and X-rays. With their deeper penetration power and non-ionizing nature, THz signals will open new inspection possibilities that are unique relative to other technologies.

An additional embodiment relates to an optical element configured for use in a system configured to determine one or more characteristics of a specimen. The optical element includes one or more materials configured to have at least some material contrast across the optical element. The one or more materials are further configured such that the optical element can be used for radiation in the THz range.

In one embodiment, the optical element is configured as a waveguide. The optical element may be configured to perform any suitable waveguide functions known in the art. In another embodiment, the optical element is configured as a filter. The optical element may be configured to perform any suitable filtering functions known in the art. In an additional embodiment, the optical element is configured as a beam splitter. The optical element may be configured to perform any suitable beam splitting functions known in the art.

In some embodiments, the optical element is configured as a photonic crystal optical element. FIG. 19 illustrates examples of two-dimensional (2D) photonic crystal structures included in a presentation titled “Photonic Crystals: Periodic Surprises in Electromagnetism” by Steven G. Johnson, MIT, which can be found at http://ab-initio.mit.edu/photons/tutorial/L4-slabs.pdf. As shown in FIG. 19, the 2D photonic crystal structures may include dielectric rods 258 arranged in different arrays to produce different fields 260. Photonic crystal devices have advantages such as the ability to focus radiation to a spot much smaller than the wavelength, produce substantially sharp filters, etc. However, the optical element may alternatively be configured as a conventional (e.g., non-photonic crystal) optical element. In addition, conventional waveguides may be easily combined with photonic crystal devices and structures using the fabrication techniques described further herein.

In one embodiment, the one or more materials include ink printed on a substrate. The ink may include any suitable ink. In another embodiment, the one or more materials include a dielectric material, which may include any suitable dielectric material known in the art. In an additional embodiment, the one or more materials include a semiconductive material, which may include any suitable semiconductive material. In a further embodiment, the one or more materials include a metal material, which may include any suitable metal material known in the art. In some embodiments, the one or more materials include a plastic material, which may include any suitable plastic material known in the art. In addition, the optical element may include some combination of the above-described materials (e.g., one or more inks, one or more dielectric materials, one or more semiconductive materials, one or more metal materials, one or more plastic materials, or some combination thereof).

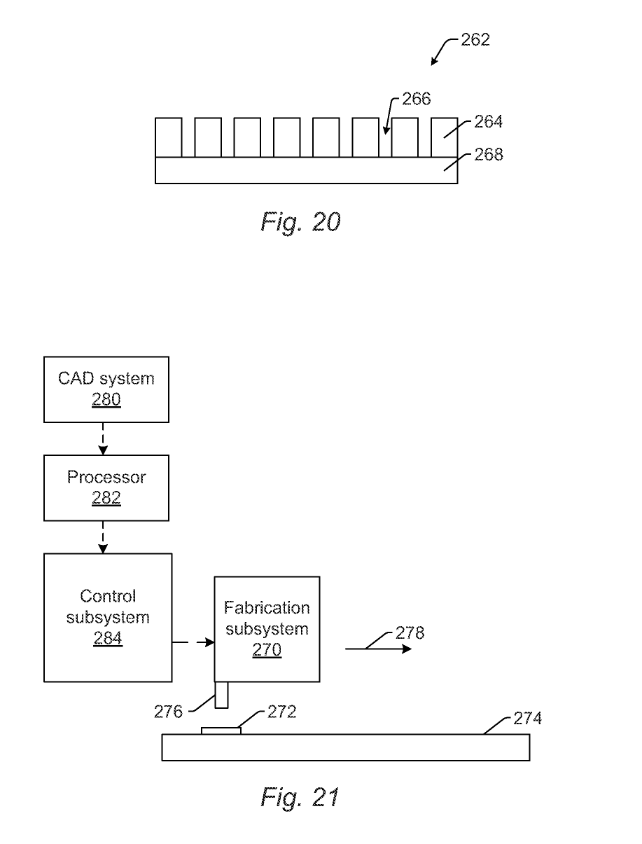

In one embodiment, the one or more materials include a material having openings formed therein. For example, one embodiment of an optical element configured for use in a system configured to determine one or more characteristics of a specimen is shown in FIG. 20. As shown in FIG. 20, optical element 262 includes material 264 having openings 266 formed therein. Material 264 is formed on material 268. Materials 264 and 268 may include any of the materials described herein. For example, material 264 may include ink, a dielectric material, a semiconductive material, a metal material, or a plastic material. Material 268 may include, for example, a dielectric material, a semiconductive material, a metal material, or a plastic material. Openings 266 may have any suitable configuration (e.g., any suitable arrangement in material 264, dimensions, etc.), which may vary depending on the field that the optical element will be used to create in the system.

In addition, although the optical element shown in FIG. 20 includes material 264 formed on material 268, it is to be understood that the optical element may or may not include material 268. For example, in one embodiment, the one or more materials include a single material (material 264, which may include any of the materials described herein) having openings formed therein, and the openings create the material contrast. In this manner, the optical element may be formed of a single material with or without a substrate formed of another material. Furthermore, the structures of the optical element formed by materials 264 and 268 may each be formed of one or more materials (e.g., a substrate formed by material 268 may be formed of one or more dielectric materials).

In one embodiment, the openings are filled with air. For example, the optical element may be disposed in an ambient environment, and the openings (or holes) may naturally fill with air thereby creating the material contrast suitable for formation of a photonic crystal or other optical element described herein. In another such embodiment, the openings are filled with a vacuum. For example, the optical element may be disposed within a vacuum or a vacuum may be created near the optical element thereby creating a vacuum in the openings thereby creating the material contrast suitable for formation of a photonic crystal or other optical element described herein. In this manner, the embodiments of the optical elements described herein may include one or more materials, which may include one or more dielectric materials, one or more semiconductive materials, one or more metal materials, one or more plastic materials, air, vacuum, or some combination thereof.

In another embodiment, the one or more materials form patterned features of the optical element. The patterned features may have any suitable shape and dimensions and may be positioned in any suitable arrangement. For example, the patterned features may include openings such as those described above having a generally cylindrical shape or, in the inverse, rods having a generally cylindrical shape formed of a material such as a dielectric material. In some embodiments, the one or more materials include ink printed on a substrate, and each of the patterned features is formed of multiple spots of the ink. For example, the patterned features may include multiple spots formed one on top of another to achieve a desired thickness. In addition, or alternatively, the patterned features may include multiple spots of the ink that do not overlap one another and/or partially overlap one another to achieve a desired shape of the features, a desired size of the features, and/or a desired thickness gradient of the patterned features. In another such embodiment, each of the patterned features has a size of about 10 microns to about 100 microns. For example, for the cases of visible and near infrared (NIR) radiation, the features may have sizes of about tens of nanometers to hundreds of nanometers. However, for THz radiation, the feature sizes may be tens of microns to about hundreds of microns. In some embodiments, the one or more materials include a substrate formed of a plastic material. For example, some of the materials used for THz optics are plastics, and the substrate may include any suitable plastic material. Each of the embodiments of the optical element described above may be further configured according to any other embodiments described herein. In addition, each of the embodiments of the optical elements described above may be included in any of the system embodiments described herein.

A further embodiment relates to a system configured to fabricate an optical element. The optical element may be configured for use in a system configured to determine one or more characteristics of a specimen, which may include any of the systems described herein. FIG. 21 illustrates one embodiment of a system configured to fabricate an optical element. The system includes a fabrication subsystem configured to create at least some material contrast across the optical element in one or more materials of the optical element to thereby fabricate the optical element. The one or more materials are configured such that the optical element can be used for radiation in the THz range.

As shown in FIG. 21, one system configured to fabricate the optical element includes fabrication subsystem 270 that is configured to form one or more materials 272 on substrate 274 to thereby fabricate the optical element. In addition, the fabrication subsystem may include nozzle 276 through which the fabrication subsystem dispenses the one or more materials onto the substrate. The nozzle may have any suitable configuration known in the art, and the nozzle configuration may affect the drop size of the one or more materials on the substrate. Therefore, fabrication subsystems that have different nozzle configurations may be selected for use for fabricating the optical element based on the selected drop size.

In one embodiment, fabrication subsystem 270 includes a print head configured to form the one or more materials on a substrate, and the one or more materials include ink. The print head may include any suitable print head known in the art. For example, the print head may include an inkjet print head, and many commercially available inkjet print heads may be suitable for use in the embodiments described herein. In addition, an inkjet printer may be fitted with cartridges filled with the appropriate precursor materials (e.g., the ink). Therefore, an optical element described herein can be fabricated using an inkjet print head. In this manner, the system shown in FIG. 21 may be used to create THz devices using inkjet technology. In addition, the fabrication subsystem may be configured to form one or more materials on the substrate sequentially by scanning across the substrate in a direction such as that shown by arrow 278. Substrate 274 may be further configured as described herein.

In this manner, the fabrication subsystem may be configured to use commercially available inkjet printing technology to create both conventional and photonic optical devices. Because the wavelength of THz radiation is somewhat larger than the resolution available on inkjet printers and because the required thickness buildup is also similar to the requirement for THz waveguides, inkjet technology is particularly well suited for this purpose. Furthermore, some of the materials used for THz optics are plastics. In addition, as described above, the one or more materials may include a substrate formed of a plastic material. Such materials are particularly well suited for inkjet deposition compared with conventional dielectrics, metals, and semiconductors.

Although print heads such as those described above may be particularly advantageous for use in systems configured to fabricate the optical elements described herein (e.g., for fabricating patterned features having sizes described herein), such print heads are by no means the only fabrication subsystem that can be used in the systems. For example, in one embodiment, the fabrication subsystem includes a lithography system, which may include any suitable lithography system known in the art such as an optical lithography system, an extreme ultraviolet (EUV) lithography system, an imprint lithography system, etc. In another embodiment, the fabrication subsystem includes a deposition system, which may include any suitable deposition system known in the art such as a chemical vapor deposition (CVD) system, a plasma-enhanced CVD (PE-CVD) system, an atomic layer deposition (ALD) system, a physical vapor deposition (PVD) system such as a sputtering based PVD system, etc. In an additional embodiment, the fabrication subsystem includes an etch system, which may include any suitable etch system known in the art. In a further embodiment, the fabrication subsystem includes a spin processing system, which may include any suitable spin processing system known in the art configured to perform any spin processing such as wet chemical etching, coating, cleaning, etc. Furthermore, the fabrication subsystem may include one or more such systems (e.g., a lithography system and an etch system). In this manner, in addition to being deposited by an inkjet, the patterned features of the optical element may be formed by some combination of lithography, spin processing, deposition, etch, etc.

In another embodiment, the system includes a computer aided design (CAD) system configured to generate a design for patterned features of the optical element formed by the one or more materials. For example, as shown in FIG. 21, the system may include CAD system 280 configured as described above. The CAD system may include any suitable CAD system known in the art that can be configured to generate the design as described above. In some such embodiments, the system also includes a processor configured to perform one or more electromagnetic calculations to verify the design. For example, as shown in FIG. 21, the system may include processor 282 configured as described above. Processor 282 may be coupled to CAD system 280 (e.g., as described further herein) such that the processor can receive the design generated by the CAD system. The processor may be configured to perform any suitable electromagnetic calculations to verify the design. In this manner, a CAD system may be used to define the structures of the optical element, possibly in conjunction with electromagnetic calculations for the verification of the design. The processor may be further configured as described herein.

The system shown in FIG. 21 may also include control subsystem 284 configured to control fabrication subsystem 270 based on the design verified by the processor such that the one or more materials formed on substrate 274 have the verified design. Control subsystem 284 may be configured to receive the verified design from processor 282. For example, control subsystem 284 may be coupled to processor 282 as described herein. The control subsystem may include any suitable hardware and/or software that can be configured to control the fabrication subsystem.

The optical element fabricated by the system may be configured as described above. For example, as described above, the optical element may be configured as a waveguide. In another embodiment, the optical element is configured as a filter. In some embodiments, the optical element is configured as a beam splitter. In a further embodiment, the optical element is configured as a photonic crystal optical element. Alternatively, the optical element may be configured as a conventional (e.g., non-photonic crystal) optical element. In this manner, the system embodiments described herein may perform a method for fabrication of THz waveguides and other THz optical devices. In addition, the system embodiments described herein provide a relatively low cost, versatile method of manufacturing THz optical devices such as waveguides, filters, splitters, etc.

In one embodiment, the one or more materials include ink printed on a substrate. In another embodiment, the one or more materials include a dielectric material, which may include any suitable dielectric material known in the art. In an additional embodiment, the one or more materials include a semiconductive material, which may include any suitable semiconductive material known in the art. In a further embodiment, the one or more materials include a metal material, which may include any suitable metal material known in the art. In yet another embodiment, the one or more materials include a plastic material, which may include any suitable plastic material known in the art.

In one embodiment, the one or more materials include a material having openings formed therein. In one such embodiment, the openings are filled with air. In another such embodiment, the openings are filled with a vacuum. In an additional embodiment, the one or more materials include a single material having openings formed therein, and the openings create the material contrast.

In another embodiment, the one or more materials form patterned features of the optical element. In one such embodiment, the one or more materials include ink printed on a substrate, and each of the patterned features is formed of multiple spots of the ink. For example, multiple layers can be built up from the precursor materials in such a manner as to create the desired 2D or one-dimensional structure. In another such embodiment, each of the patterned features has a size of about 10 microns to about 100 microns. For example, for the cases of visible and NIR radiation, the features may have sizes of about tens of nanometers to hundreds of nanometers. However, for THz radiation, the feature sizes may be tens of microns to about hundreds of microns. Creating these features lithographically may be expensive and inflexible. However, THz waveguides are currently fabricated by micromachining or lithography. In addition, IR waveguides are currently manufactured primarily by lithography. Creating these features using precision mechanical fabrication techniques is prohibitively difficult, expensive, and less flexible than those described herein. However, microwave waveguides are currently made primarily using precision mechanical fabrication techniques. In addition, mechanical construction of THz waveguides requires prohibitively tight tolerances and relatively small feature sizes. Inkjet technology is inexpensive, flexible, well-characterized, and particularly compatible with the materials appropriate for THz optical devices. Therefore, the system embodiments described herein are advantageous in cost, flexibility, and performance. Furthermore, low resolution, maskless lithography may be able to achieve some of the advantages of the embodiments described herein, but not all of the advantages. Moreover, the embodiments of systems for fabricating an optical element and the optical elements described herein may be enabling technology for applications of THz technology such as semiconductor applications and applications in other fields.

Further modifications and alternative embodiments of various aspects of the invention may be apparent to those skilled in the art in view of this description. For example, systems and methods for determining one or more characteristics of a specimen using radiation in the THz range are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. An optical element configured for use in a system configured to determine one or more characteristics of a specimen, wherein the optical element comprises one or more materials configured to have at least some material contrast across the optical element, and wherein the one or more materials are further configured such that the optical element can be used for radiation in the terahertz range.

2. The optical element of claim 1, wherein the optical element is further configured as a waveguide.

3. The optical element of claim 1, wherein the optical element is further configured as a filter.

4. The optical element of claim 1, wherein the optical element is further configured as a beam splitter.

5. The optical element of claim 1, wherein the optical element is further configured as a photonic crystal optical element.

6. The optical element of claim 1, wherein the one or more materials comprise ink printed on a substrate.

7. The optical element of claim 1, wherein the one or more materials comprise a dielectric material.

8. The optical element of claim 1, wherein the one or more materials comprise a semiconductive material.

9. The optical element of claim 1, wherein the one or more materials comprise a metal material.

10. The optical element of claim 1, wherein the one or more materials comprise a plastic material.

11. The optical element of claim 1, wherein the one or more materials comprise a material having openings formed therein, and wherein the openings are filled with air.

12. The optical element of claim 1, wherein the one or more materials comprise a material having openings formed therein, and wherein the openings are filled with a vacuum.

13. The optical element of claim 1, wherein the one or more materials comprise a single material having openings formed therein, and wherein the openings create the material contrast.

14. The optical element of claim 1, wherein the one or more materials form patterned features of the optical element.

15. The optical element of claim 1, wherein the one or more materials form patterned features of the optical element, wherein the one or more materials comprise ink printed on a substrate, and wherein each of the patterned features is formed of multiple spots of the ink.

16. The optical element of claim 1, wherein the one or more materials form patterned features of the optical element, and wherein each of the patterned features has a size of about 10 microns to about 100 microns.

17. The optical element of claim 1, wherein the one or more materials comprise a substrate formed of a plastic material.

18. A system configured to fabricate an optical element, wherein the system comprises a fabrication subsystem configured to create at least some material contrast across the optical element in one or more materials of the optical element to thereby fabricate the optical element, and wherein the one or more materials are configured such that the optical element can be used for radiation in the terahertz range.

19. The system of claim 18, wherein the fabrication subsystem comprises a print head configured to form the one or more materials on a substrate, and wherein the one or more materials comprise ink.

20. The system of claim 18, wherein the fabrication subsystem comprises a lithography system.

21. The system of claim 18, wherein the fabrication subsystem comprises a deposition system.

22. The system of claim 18, wherein the fabrication subsystem comprises an etch system.

23. The system of claim 18, wherein the fabrication subsystem comprises a spin processing system.

24. The system of claim 18, further comprising a computer aided design system configured to generate a design for patterned features of the optical element formed by the one or more materials.

25. The system of claim 18, further comprising a computer aided design system configured to generate a design for patterned features of the optical element formed by the one or more materials and a processor configured to perform one or more electromagnetic calculations to verify the design.

26. The system of claim 18, wherein the optical element is configured as a waveguide.

27. The system of claim 18, wherein the optical element is configured as a filter.

28. The system of claim 18, wherein the optical element is configured as a beam splitter.

29. The system of claim 18, wherein the optical element is configured as a photonic in crystal optical element.

30. The system of claim 18, wherein the one or more materials comprise ink printed on a substrate.

31. The system of claim 18, wherein the one or more materials comprise a dielectric material.

32. The system of claim 18, wherein the one or more materials comprise a semiconductive material.

33. The system of claim 18, wherein the one or more materials comprise a metal material.

34. The system of claim 18, wherein the one or more materials comprise a plastic material.

35. The system of claim 18, wherein the one or more materials comprise a material having openings formed therein, and wherein the openings are filled with air.

36. The system of claim 18, wherein the one or more materials comprise a material having openings formed therein, and wherein the openings are filled with a vacuum.

37. The system of claim 18, wherein the one or more materials comprise a single material having openings formed therein, and wherein the openings create the material contrast.

38. The system of claim 18, wherein the one or more materials form patterned features of the optical element.

39. The system of claim 18, wherein the one or more materials form patterned to features of the optical element, wherein the one or more materials comprise ink printed on a substrate, and wherein each of the patterned features is formed of multiple spots of the ink.

40. The system of claim 18, wherein the one or more materials form patterned features of the optical element, and wherein each of the patterned features has a size of about 10 microns to about 100 microns.

41. The system of claim 18, wherein the one or more materials comprise a substrate formed of a plastic material.
